(19) United States
(12) Patent Application Publication
(10) Pub. No.: US 2026/0181909 A1
(43) Pub. Date: Jun. 25, 2026

(54) MEMORY DEVICE AND METHOD FOR MANUFACTURING A MEMORY CELL ARRANGEMENT USING A PRECONDITIONING OPERATION

(71) Applicant: Ferroelectric Memory GmbH, Dresden (DE)

(72) Inventors: Michael Hoffmann, Dresden (DE); Johannes Ocker, Dresden (DE)

(21) Appl. No.: 19/000,965

(22) Filed: Dec. 24, 2024

(51) Int. Cl. H10B 53/30; G11C 11/22; H10B 53/40; H10N 70/00; H10N 70/20; H10N 79/00

(52) U.S. Cl. CPC H10B 53/30; G11C 11/221; H10B 53/40; H10N 70/041; H10N 70/20; H10N 79/00

(57) ABSTRACT

Various aspects relate to a method including: forming a plurality of memory cells, wherein each of the plurality of memory cells includes a respective spontaneously-polarizable memory element in an as-formed condition; carrying out a preconditioning operation to concurrently bring the respective spontaneously-polarizable memory element of each of the plurality of memory cells from the as-formed condition into an operable condition to allow for a writing of each of the plurality of memory cells after the preconditioning operation is carried out; wherein the preconditioning operation includes providing a periodic precondition signal at each memory cell of the plurality of memory cells, wherein each cycle of the periodic precondition signal includes a first precondition voltage pulse having a first polarity and a second precondition voltage pulse having a second polarity opposite to the first polarity, and wherein the periodic precondition signal has a frequency equal to or less than 150 Hz.

### TECHNICAL FIELD

Various aspects relate to a memory device and methods of manufacturing a memory cell arrangement (e.g., a method of manufacturing a memory device including the memory cell arrangement) using a preconditioning operation.

### BACKGROUND

In general, various computer memory technologies have been developed in semiconductor industry. A fundamental building block of a computer memory may be referred to as memory cell. The memory cell may be an electronic circuit that is configured to store an information (e.g., bitwise). As an example, the memory cell may have at least two memory states representing, for example, a logic “1” and a logic “0”. In general, the information may be maintained (stored) in a memory cell until the memory state of the memory cell is modified, e.g., in a controlled manner. The information stored in the memory cell may be obtained (read out) by determining in which of the memory states the memory cell is residing in. At present, various types of memory cells may be used to store data. By way of example, a type of memory cell may include a thin film of a spontaneous-polarizable material, e.g., a ferroelectric material or a configuration of an anti-ferroelectric material, whose polarization state may be changed in a controlled fashion to store data in the memory cell, e.g., in a non-volatile manner. A memory cell or an arrangement of memory cells may be integrated, for example, on a wafer or a chip together with one or more logic circuits.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1A shows various aspects of a spontaneously polarizable capacitor structure in a schematic view;

FIG. 1B and FIG. 1C each show a memory cell including the spontaneously polarizable capacitor structure according to various aspects;

FIG. 2 shows an exemplary memory cell arrangement including a plurality of memory cells and various control lines for addressing the plurality of memory cells according to various aspects;

FIG. 3 shows an example of a typical hysteresis curve of a remanent-polarizable memory structure that plots the polarization as a function of the voltage across it;

FIG. 4 schematically shows a preconditioning of the spontaneously polarizable capacitor structure according to various aspects;

FIG. 5 shows an exemplary precondition voltage pulse according to various aspects;

FIG. 6 shows various aspects of an exemplary precondition signal;

FIG. 7 shows the switchable polarization as a function of the cycling time for different frequencies of the precondition signal and for different temperatures according to various aspects;

FIG. 8 shows the switchable polarization as a function of the cycling time for different frequencies of the precondition signal and for different duty cycles according to various aspects;

FIG. 9 shows various aspects of the switchable polarization for different voltage amplitudes of the precondition signal according to various aspects;

FIG. 10 shows an exemplary precondition signal according to various aspects; and

FIG. 11 and FIG. 12 each show a flow diagram of a method for manufacturing a memory cell arrangement according to various aspects.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects. Various aspects are described in connection with methods and various aspects are described in connection with devices (e.g., a memory cell, or a memory capacitor). However, it may be understood that aspects described in connection with methods may similarly apply to the devices, and vice versa.

In the semiconductor industry, the integration of non-volatile memory technologies, sensor technologies, transmitter technologies, electronic filter technologies, receiver technologies, and the like may be useful for various types of devices and applications. According to various aspects, an electronic device, e.g., a non-volatile memory may be integrated on a chip.

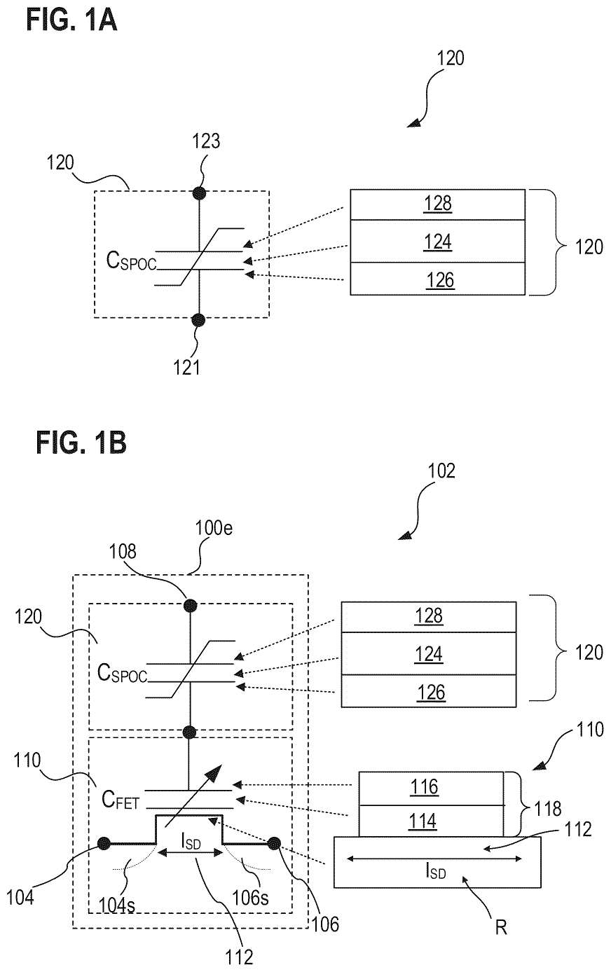

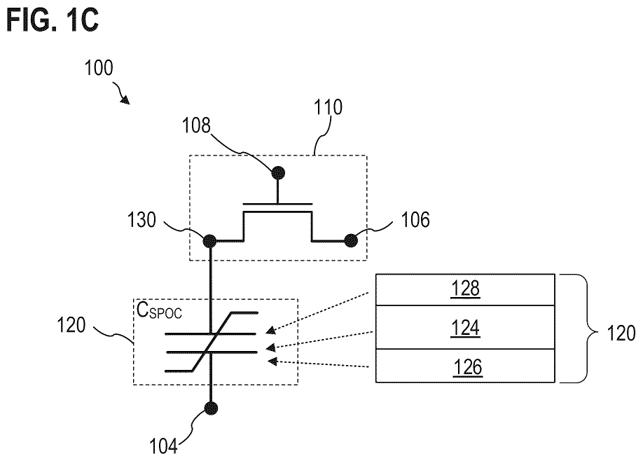

FIG. 1A shows various aspects of a spontaneously polarizable capacitor, SPOC, structure 120. The SPOC structure 120 may provide a memory structure of a memory cell (therefore, in some aspects also referred to as memory layer stack). The SPOC structure 120 may include at least two electrodes (e.g., two electrode layers), such as a first electrode 126 and a second electrode 128. The SPOC structure 120 may include a memory element 124. The memory element 124 may be disposed between the first electrode 126 and the second electrode 128. The memory element 124 may be disposed in direct physical contact with the first electrode 126 and in direct physical contact with the second electrode 128. The memory element 124 may include or may consist of a spontaneously polarizable material. A memory element 124 including or consisting of a spontaneously polarizable material may also be referred to as spontaneously-polarizable memory element 124. For example, the spontaneously polarizable material may be a remanent polarizable material, such as a ferroelectric material, or a non-remanent polarizable material, such as an anti-ferroelectric material. A memory element including or consisting of a spontaneously polarizable material may be understood such that the memory element has (e.g., within the framework of the SPOC structure 120) spontaneously polarizable properties. According to various aspects, the first electrode 126, the second electrode 128, and the memory element 124 may form the SPOC structure 120. The SPOC structure 120 may, in some aspects, also be referred to as memory capacitor.

The SPOC structure 120 may be part of or may form a memory cell 102. The first electrode 126 may be coupled to a first terminal 121 and the second electrode 128 may be coupled to a second terminal 123.

The spontaneously-polarizable memory element 124 may show a hysteresis in the (voltage (drop) dependent) polarization. The spontaneously-polarizable memory element 124 may show non-remanent spontaneous polarization (e.g., may show anti-ferroelectric properties), e.g., the spontaneously-polarizable memory element may have no or no substantial remanent polarization remaining in the case that no voltage drops over the spontaneously-polarizable memory element 124. In other aspects, the spontaneously-polarizable memory element 124 may show remanent spontaneous polarization (e.g., may show ferroelectric properties), e.g., the spontaneously-polarizable memory element 124 may have a remanent polarization or a substantial remanent polarization remaining in the case that no voltage drops over the spontaneously-polarizable memory element.

The terms “spontaneously polarized” or “spontaneous polarization” may be used herein, for example, with reference to the polarization capability of a material beyond dielectric polarization. A “spontaneously-polarizable” (or “spontaneous-polarizable”) material may be or may include a spontaneously-polarizable material that shows a remanence, e.g., a ferroelectric material, and/or a spontaneously-polarizable material that shows no remanence, e.g., an anti-ferroelectric material. The coercivity of the spontaneously-polarizable material may be a measure of the strength of the reverse polarizing electric field that may be required to remove a remanent polarization.

A spontaneous polarization (e.g., a remanent or non-remanent spontaneous polarization) may be evaluated via analyzing one or more hysteresis measurements (e.g., hysteresis curves), e.g., in a plot of polarization, P, versus electric field, E, in which the material is polarized into opposite directions. The polarization capability of a material (dielectric polarization, spontaneous polarization, and a remanence characteristics of the polarization) may be analyzed using capacity spectroscopy, e.g., via a static (C-V) and/or time-resolved measurement or by polarization-voltage (P-V) or positive-up-negative-down (PUND) measurements.

According to various aspects, in various types of applications, e.g., in memory technology, a remanent polarization as low as 0 μC/cm² to 3 μC/cm² may be regarded as no substantial remanent polarization. Such low values of a remanent polarization may be present in a layer or material due to undesired effects, e.g., due to a not ideal layer formation. According to various aspects, in various types of applications, e.g., in memory technology, a remanent polarization greater than 3 μC/cm² may be regarded as substantial remanent polarization. Such a substantial remanent polarization may allow for storing information as a function of a polarization state of a spontaneously polarizable layer or a spontaneously polarizable material.

In a usual capacitor structure, the amount of charge stored therein may be used to define a memory state (e.g., first amount of charge stored in the capacitor structure may define a first memory state and a second amount of charge stored in the capacitor structure may define a second memory state.

In general, a remanent polarization (also referred to as retentivity or remanence) may be present in a material layer in the case that the material layer may remain polarized upon reduction of an applied electric field (E) to zero, therefore, a certain value for the electrical polarization (P) of the material layer may be detected. Illustratively, a polarization remaining in a material when the electric field is reduced to zero may be referred to as remanent polarization. Therefore, the remanence of a material may be a measure of the residual polarization in the material in the case that an applied electric field is removed. In general, ferroelectricity and anti-ferroelectricity may be concepts to describe a spontaneous polarization of a material similar to ferromagnetism and anti-ferromagnetism used to describe remanent magnetization in magnetic materials. According to various aspects, an electric coercive field, E_{C}, (also referred to as coercive field) may be or may represent the electric field required to depolarize a remanent-polarizable layer.

According to various aspects, the spontaneously-polarizable memory element 124 may include or may consist of a remanent-polarizable material. A remanent-polarizable material may be a material that is remanently polarizable and shows a remanence of the spontaneous polarization, such as a ferroelectric material. In other aspects, remanent-polarizable material may be a material that is spontaneously polarizable and that shows no remanence, e.g., an anti-ferroelectric material under the additional conditions that measures are implemented to generate an internal electric-field within the anti-ferroelectric material. Hence, a non-remanently polarizable material, such as an anti-ferroelectric (“antiferroelectric”) material may exhibit remanent polarizable properties within certain structures. An internal electric-field within an anti-ferroelectric material may be caused (e.g., applied, generated, maintained, as examples) by various strategies: e.g., by implementing floating nodes that may be charged to voltages different from zero volts, and/or by implementing charge storage layers, and/or by using doped layers, and/or by using electrode layers that adapt electronic work-functions to generate an internal electric field, by using an encapsulation structure which introduces compressive stress or tensile stress onto the memory element 124, thereby establishing the spontaneously polarizable properties, only as examples. The spontaneously-polarizable memory element 124 including or being made of a remanent-polarizable material may be referred to herein as remanent-polarizable memory element (e.g., as remanent-polarizable layer).

In some aspects, the spontaneous-polarizable material (e.g., a remanent-polarizable material) may be based on at least one metal oxide. Illustratively, a composition of the spontaneous-polarizable material may include the at least one metal oxide for more than 50%, or more than 66%, or more than 75%, or more than 90%. In some aspects, the spontaneous-polarizable material may include one or more metal oxides. The spontaneous-polarizable material may include (or may be based on) at least one of HfₐO_{b}, ZrₐO_{b}, SiₐO_{b}, YₐO_{b}, as examples, wherein the subscripts “a” and “b” may indicate the number of the respective atom in the spontaneous-polarizable material.

In some aspects, the spontaneous-polarizable material (e.g., the remanent-polarizable material) may be or may include a ferroelectric material, illustratively the memory element 124 may be ferroelectric memory element (for example a ferroelectric layer). A ferroelectric material may be an example of a material used in a spontaneously-polarizable memory element (e.g., in a remanent-polarizable element). The ferroelectric material may be or may include at least one of the following: hafnium oxide (ferroelectric hafnium oxide, HfO₂), zirconium oxide (ferroelectric zirconium oxide, ZrO₂), a (ferroelectric) mixture of hafnium oxide and zirconium oxide (also referred to as hafnium zirconium oxide. Ferroelectric hafnium oxide may include any form of hafnium oxide that may exhibit ferroelectric properties. Ferroelectric zirconium oxide may include any form of zirconium oxide that may exhibit ferroelectric properties. This may include, for example, hafnium oxide, zirconium oxide, a solid solution of hafnium oxide and zirconium oxide (e.g., but not limited to it, a 1:1 mixture) or hafnium oxide and/or zirconium oxide doped or substituted with one or more of the following elements (non-exhaustive list): silicon, aluminum, gadolinium, yttrium, lanthanum, strontium, zirconium, any of the rare earth elements or any other dopant (also referred to as doping agent) that is suitable to provide or maintain ferroelectricity in hafnium oxide or zirconium oxide. The ferroelectric material may be doped at a concentration from about 2 mol % to about 6 mol %, only as an example.

In some aspects, the spontaneous-polarizable material may include hafnium oxide (e.g., may consist of hafnium oxide, hafnium zirconium oxide (e.g., Hf_{0.75}Zr_{0.25}O₂ or Hf_{0.5}Zr_{0.5}O₂), hafnium silicon oxide, hafnium lanthanum oxide, or hafnium lanthanum zirconium oxide), zirconium oxide, and/or aluminum nitride (e.g., may consist of aluminum nitride, aluminum scandium nitride or aluminum boron nitride). In some aspects, the spontaneous-polarizable material may include or may consist of Hf₁₋ₓZrₓO₂, Hf₁₋ₓSiₓO₂, Hf₁₋ₓLaₓO₂, Hf_{1-x-y}LaₓZr_{y}O₂, Al₁₋ₓScₓN, or Al₁₋ₓBₓN.

The spontaneously polarizable material of the memory element 124 may include or may consist of lead zirconate titanate (Pb[ZrₓTi₁₋ₓ]O₃, PZT) or strontium bismuth tantalate (Sr₂Bi₂TaO₉, SBT). However, there are several disadvantages for integrating PZT and SBT in complementary metal-oxide-semiconductor (CMOS):
Polycrystalline PZT or SBT films may require a thickness of more than 70 nm in order to ensure that the complete film is ferroelectric. However, the lateral dimension in CMOS integration may not be scalable such that the thick films lead to huge height difference between the SPOC structure 120 and the logic area forming below the interlayer metallization.
PZT and SBT require four elements and cannot be deposited using atomic layer deposition (ALD). Hence, PZT and SBT cannot be used for a 3D-integration of the SPOC structure 120, but merely for planar structures.
PZT and SBT include elements which may contaminate CMOS facilities. PZT even includes lead (Pb) which is considered toxic. This may require a special encapsulation of the whole SPOC structure 120. Further, dedicated tools may be required for depositing the toxic elements.
PZT and SBT have a comparatively small band gap (e.g., 3.0 to 3.5 eV for PZT). Hence, PZT and SBT cannot be used for devices that require low leakage currents through the SPOC structure 120.

As described, the spontaneously polarizable material of the memory element 124 may consist of hafnium zirconium oxide (Hf₁₋ₓZrₓO₂, HZO) with 0≤x≤1 (i.e., consisting of hafnium oxide in the case of x=0 and consisting of zirconium oxide in the case of x=1). There are several advantages of HZO for CMOS integration:
HZO films are ferroelectric or antiferroelectric down to a thickness of 1 nm. Hence, the integration of the SPOC structure 120 in lateral dimension is scalable to a maximum degree.
HZO films can be deposited using ALD. This allows to manufacture SPOC structure 120 having curved structures and allow a 3D-integration of the SPOC structure 120.
HZO films are CMOS compatible and do not include any toxic elements. Hence, an encapsulation of the SPOC structure 120 may be optional and the standard CMOS equipment can be used.
It may be possible to crystallize the HZO into the ferroelectric phase by annealing at temperatures in a range from about 300° C. to about 400° C. This allows an integration of the SPOC structure 120 as part of the interlayer metallization.
HZO films have a large band gap (e.g., 5.8 eV for hafnium oxide). Thus, HZO can be used for devices that require a low leakage current.

It is understood that a layer which is described as consisting of hafnium zirconium oxide (HZO) may include an alternating sequence of first sublayers substantially consisting of zirconium oxide and second sublayers substantially consisting of hafnium oxide, or vice versa.

According to various aspects, the memory capacitor as provided by the SPOC structure 120 may be or may include a ferroelectric capacitor (FeCAP) or an anti-ferroelectric capacitor (AFeCAP). An information may be stored by the memory capacitor via at least two remanent polarization states of the SPOC structure 120. The programming of the SPOC structure 120 (illustratively the storage of information therein) may be carried out by providing (e.g., applying) an electric field to thereby set or change the remanent polarization state of the spontaneously polarizable memory element 124. Illustratively, the spontaneous-polarizable material (e.g., a ferroelectric material, e.g., an anti-ferroelectric material) may be used to store data in non-volatile manner in integrated circuits.

It may be understood that, even though various aspects refer to a memory element including or being made of a spontaneously-polarizable material, other memory elements whose state may be altered by an electric field provided across a capacitive memory structure may be used as long as the structure of the material can be changed via application of an electric field, as described herein.

The SPOC structure 120 may have a capacitive configuration with a (first) capacitance, C_{SPOC}, associated therewith (see equivalent circuit 100e in FIG. 1B with respect to the capacitive properties). The first electrode 126, the memory element 124, and the second electrode 128 may form a memory capacitor. In some aspects, the memory capacitor may be a planar layer stack; however, other shapes may be suitable as well, e.g., curved shapes, angled shapes, coaxially aligned shapes, as examples. Illustratively, the SPOC structure 120 may include planar electrodes, or, in other aspects, the SPOC structure 120 may be configured as 3D capacitor including, for example, angled or curved electrodes.

FIG. 1B and FIG. 1C each show a memory cell 102 including the spontaneously polarizable capacitor structure 120 according to various aspects.

With reference to FIG. 1B, the memory cell 102 may be a field-effect transistor (FET) based capacitive memory structure (e.g., including a ferroelectric FET, FeFET). The memory cell 102 may include a field-effect transistor structure 110 and the SPOC structure 120. The SPOC structure 120 may be coupled to a gate structure 118 of the FET. The gate structure 118 may include a gate isolation 114 and a gate electrode 116. The gate structure 118 is illustrated exemplarily as a planar gate stack; however, it is understood that the planar configurations shown in FIG. 1A and FIG. 1B are examples, and that other field-effect transistor designs may include a gate structure 118 with a non-planar shape, for example a trench gate transistor design, a vertical field-effect transistor design, or other designs, such as a fin-FET design.

The memory cell 102 may have a first terminal 104 (e.g., a source terminal), a second terminal 106 (e.g., a drain terminal), and a third terminal 108 (e.g., a gate terminal). The memory cell 102 may include a field-effect transistor structure 110. The field-effect transistor structure 110 may include a first source/drain region 104s (e.g., a source region). The first source/drain region 104s may be connected to the first terminal 104 of the memory cell 102. The field-effect transistor structure 110 may include a second source/drain region 106s (e.g., a drain region). The second source/drain region 106s may be connected to the second terminal 106 of the memory cell 102. The field-effect transistor structure 110 may include the gate structure 108g (e.g., a gate region). The gate structure 108g may be connected to the third terminal 108 of the memory cell 102.

The gate structure 118 may define a channel region 112, e.g., provided in a semiconductor portion (e.g., in a semiconductor layer, in a semiconductor die, etc.). The gate structure 118 may allow for a control of an electrical behavior (e.g., a resistance R) of the channel region 112, e.g., a current flow in the channel region 112 may be controlled (e.g., allowed, increased, prevented, decreased, etc.). In some aspects, the gate structure 118 may, for example, allow to control (e.g., allow or prevent) a source/drain current, I_{SD}, from a first source/drain region of the field-effect transistor structure 110 to a second source/drain region of the field-effect transistor structure 110. The channel region 112 and the source/drain regions may be formed, e.g., via doping one or more semiconductor materials or by the use of intrinsically doped semiconductor materials, within a layer and/or over a layer. With respect to the operation of the field-effect transistor structure 110, a voltage may be provided at the gate electrode 116 to control the current flow, I_{SD}, in the channel region 112, the current flow, I_{SD}, in the channel region 112 being caused by voltages supplied via the source/drain regions.

According to various aspects, the semiconductor portion (illustratively, where the channel region 112 may be formed), may be made of or may include silicon. However, other semiconductor materials of various types may be used in a similar way, e.g., germanium, Group III to V (e.g., SiC), or other types, including for example carbon nanotubes, organic materials (e.g., organic polymers), etc. In various aspects, the semiconductor portion may be a wafer made of silicon (e.g., p-type doped or n-type doped). In other aspects, the semiconductor portion may be a silicon on insulator (SOI) wafer. In other aspects, the semiconductor portion may be provided by a semiconductor structure, e.g., by one or more semiconductor fins, one or more semiconductor nanosheets, one or more semiconductor nanowires, etc., disposed at a carrier.

The gate electrode 116 may include an electrically conductive material, for example, a metal, a metal alloy, a degenerate semiconductor (in other words a semiconductor material having such a high level of doping that the material acts like a metal and not anymore as a semiconductor), and/or the like. As an example, the gate electrode 116 may include or may be made of aluminum. As another example, the gate electrode 116 may include or may be made of polysilicon. According to various aspects, the gate electrode 116 may include one or more electrically conductive portions, layers, etc. The gate electrode 116 may include, for example, one or more metal layers (also referred to as a metal gate), one or more polysilicon layers (also referred to as poly-Si-gate), etc. A metal gate may include, for example, at least one work-function adaption metal layer disposed over the gate isolation 114 and an additional metal layer disposed over the work-function adaption metal layer. A poly-Si-gate may be, for example, p-type doped or n-type doped.

The gate isolation 114 may be configured to provide an electrical separation of the gate electrode 116 from the channel region 112 and further to influence the channel region 112 via an electric field generated by the gate electrode 116. The gate isolation 114 may include one or more electrically insulating layers, as an example. Some designs of the gate isolation 114 may include at least two layers including different materials, e.g., a first gate isolation layer (e.g., a first dielectric layer including a first dielectric material) and a second gate isolation layer (e.g., a second dielectric layer including a second dielectric material distinct from first dielectric material).

As illustrated by the circuit equivalent in FIG. 1B, a (second) capacitance, C_{FET}, may be associated with the field-effect transistor structure 110. Illustratively, the channel region 112, the gate isolation 114, and the gate electrode 116 may have a capacitance, C_{FET}, associated therewith, originating from the more or less conductive regions (the channel region 112 and the gate electrode 116) separated from one another by the gate isolation 114. Further illustratively, the channel region 112 may be considered as a first capacitor electrode, the gate electrode 116 as a second capacitor electrode, and the gate isolation 114 as a dielectric medium between the two capacitor electrodes. The capacitance, C_{FET}, of the field-effect transistor structure 110 may define one or more operating properties of the field-effect transistor structure 110. The configuration of the field-effect transistor structure 110 (e.g., of the gate isolation 114) may be adapted according to a desired behavior or application of the field-effect transistor structure 110 during operation (e.g., according to a desired capacitance).

In general, the capacitance, C, of a planar capacitor structure may be expressed as,

$$C = {ε}_{0} {ε}_{r} \frac{A}{d} ,$$

with ε₀ being the permittivity of the vacuum, A being the effective area of the capacitor, d being the distance of the two capacitor electrodes from one another, and εᵣ being the relative permittivity of the dielectric material disposed between two capacitor electrodes assuming that the whole gap between the two capacitor electrodes is filled with the dielectric material. It is noted that the capacitance of a non-planar capacitor structure or of a modified variant of a planar capacitor structure may be calculated based on equations known in the art.

In some aspects, the gate electrode 116 of the field-effect transistor structure 110 and the first electrode 126 of the SPOC structure 120 that is connected to the field-effect transistor structure 110 may be spatially separated from one another and electrically connected via a conductive connection, e.g., one or more metal lines. In other aspects, the gate electrode 116 of the field-effect transistor structure 110 and the first electrode 126 of the SPOC structure 120 may be in direct physical contact with one another or implemented as a single (shared) electrode. For example, an electrode layer may (as single (shared) electrode) provide both, the gate electrode 116 of the field-effect transistor structure 110 and the first electrode 126 of the SPOC structure 120.

The SPOC structure 120 may allow adapting the capacitances C_{FET}, C_{SPOC} of the respective capacitors to allow an efficient programming of the memory cell. The overall gate voltage required for switching the memory cell from one memory state into another memory state (e.g., from high threshold voltage state to low threshold voltage state, as described below), may become smaller in case the voltage distribution across the field-effect transistor structure 110 and the SPOC structure 120 is adapted such that more of the applied gate voltage drops across the memory layer of the SPOC structure 120 (e.g., across the memory element 124) than across the gate isolation of the field-effect transistor structure 110. The overall write voltage (illustratively, applied via nodes to which the field-effect transistor structure 110 and the SPOC structure 120 are connected) may thus be reduced by adapting the capacitive voltage divider. The voltage distribution may be determined by voltage divider calculations for a series connection of the capacitors.

That is, in the case that the capacitance, C_{FET}, of the field-effect transistor structure 110 is adapted (e.g., by providing a suitable gate isolation) a predefined fraction of the voltage applied to the series connection may drop across the SPOC structure 120. Accordingly, the electric field generated across the gate isolation of the field-effect transistor structure 110 underneath the SPOC structure 120 could be reduced if desired. This may lead to a reduced interfacial field stress, which may lead to a reduced wear out of the interface due to, for example, charge injection. Therefore, the reduced electric field generated across the gate isolation may lead to improved endurance characteristics of the memory cell, that is, to an increased amount of possible state reversals until the memory cell may lose or change its memory properties.

By increasing the capacitance C_{FET} of the field-effect transistor structure 110 (e.g., by providing a gate isolation including a relatively thick layer of material with high dielectric constant), the depolarization field, E_{Dep}, of the spontaneously polarizable material of the memory element 124 may be reduced. The depolarization field may be expressed by the following set of equations, wherein the indices “FET” refer to the capacitor provided by the field-effect transistor structure 110 and the indices “CAP” refer to the capacitor provided by the SPOC structure 120, as described herein:

$${V}_{FET} + {V}_{CAP} = 0 ,$$

$$D = {ε}_{0} {ε}_{FET} {E}_{FET} = {ε}_{0} {ε}_{CAP} {E}_{CAP} + P ,$$

$${E}_{CAP} ≡ {E}_{Dep} = - P {( {ε}_{0} {ε}_{CAP} ( \frac{{C}_{FET}}{{C}_{CAP}} + 1 ) )}^{- 1} .$$

The depolarization field E_{Dep} may be detrimental to data retention since, depending on its magnitude, it may depolarize the remanent-polarizable layer. However, the magnitude may be reduced by increasing the capacitance ratio C_{FET}/C_{SPOC}. Accordingly, in case the capacitance C_{FET} of the field-effect transistor structure 110 is increased, the depolarization field is reduced. This in turn improves the data retention of the memory cell.

According to various aspects, a threshold voltage of a field-effect transistor structure (and in a corresponding manner the threshold voltage of a field-effect transistor-based memory cell) may be defined as a constant current threshold voltage (referred to as V_{th(ci)}). In this case, the constant current threshold voltage, V_{th(ci)}, may be a determined gate source voltage, V_{GS}, at which the drain current (referred to as ID) is equal to a predefined (constant) current. The predefined (constant) current may be a reference current (referred to as I_{D0}) times the ratio of gate width (W) to gate length (L). The magnitude of the reference current, I_{D0}, may be selected to be appropriate for a given technology, e.g., 0.1 μA. In some aspects, the constant current threshold voltage, V_{th(ci)}, may be determined based on the following equation:

$${V}_{th ( ci )} = {V}_{GS} ( at {I}_{D} = {I}_{D 0} \cdot W / L ) .$$

A threshold voltage of a field-effect transistor structure (e.g., of the field-effect transistor structure 110) may be defined by the properties of the field-effect transistor structure (e.g., the materials, the doping, etc.), and it may thus be a (e.g., intrinsic) property of the field-effect transistor structure.

A memory cell including a field-effect transistor structure may include a first memory state, for example associated with a low threshold voltage state (referred to as LVT associated with the LVT memory state), and a second memory state, for example associated with a high threshold voltage state (referred to as HVT state associated with the HVT memory state). The high threshold voltage state may be, in some aspects, associated with a lower current flow during readout than the low threshold voltage state. The low threshold voltage state may be an electrically conducting state (e.g., associated with a logic memory state “1”, also referred to as a memory state or programmed state) and the high threshold voltage state may be an electrically non conducting state or at least less conducting than the low threshold voltage state (e.g., associated with a logic memory state “0”, also referred to as a memory state or erased state). However, the definition of the LVT state and the HVT state and/or the definition of a logic “0” and a logic “1” and/or the definition of “programmed state” and “erased state” may be selected arbitrarily. Illustratively, the first memory state may be associated with a first threshold voltage of the FET based memory cell, and the second memory state may be associated with a second threshold voltage of the FET based memory cell. However, the definition of the memory states and/or the definition of a logic “0” and a logic “1” may be selected arbitrarily.

According to various aspects, the residual polarization of the memory element 124 (e.g., the polarization of the spontaneously-polarizable material of the memory element 124) may define the memory state a memory cell is residing in. According to various aspects, a memory cell may reside in a first memory state in the case that the memory element is in a first polarization state, and the memory cell may reside in a second memory state in the case that the memory element is in a second polarization state (e.g., opposite to the first polarization state). As an example, the polarization state of the memory element may determine the amount of charge stored in the SPOC structure 120. The amount of charge stored in the SPOC structure 120 may be used to define a memory state of the memory cell. The threshold voltage of a field-effect transistor structure may be a function of the polarization state of the memory element 124, e.g., may be a function of the amount and/or polarity of charge stored in the SPOC structure 120. A first threshold voltage, e.g., a low threshold voltage V_{L-th}, may be associated with the first polarization state (e.g., with the first amount and/or polarity of stored charge), and a second threshold voltage, e.g., a high threshold voltage V_{H-th}, may be associated with the second polarization state (e.g., with the second amount and/or polarity of stored charge). A current flow from nodes to which the field-effect transistor structure and the SPOC structure 120 are coupled may be used to determine the memory state in which the memory cell is residing in.

According to various aspects, writing a memory cell or performing a write operation of a memory cell may include an operation or a process that modifies the memory state the memory cell is residing in from a (e.g., first) memory state to another (e.g., second) memory state. According to various aspects, writing a memory cell may include programming a memory cell (e.g., performing a programming operation of a memory cell), wherein the memory state the memory cell is residing in after programming may be called “programmed state”. For example, programming an n-type FET based memory cell may modify the state the memory cell is residing in from the HVT state to the LVT state, whereas programming a p-type FET based memory cell may modify the state the memory cell is residing in from the LVT state to the HVT state. According to various aspects, writing a memory cell may include erasing a memory cell (e.g., performing an erasing operation of a memory cell), wherein the memory state the memory cell is residing in after the erasing may be called “erased state”. For example, erasing an n-type FET based memory cell may modify the state the memory cell is residing in from the LVT state to the HVT state, whereas erasing a p-type FET based memory cell may modify the state the memory cell is residing in from the HVT state to the LVT state.

Another example of a memory cell having at least two distinct states is a phase-change memory cell. The phase-change memory cell may include a phase change portion. The phase-change portion may be used to implement memory functions, e.g., in a memory cell. The phase-change portion may include a first phase state and a second phase state. For example, a phase-change memory cell may change from a first phase state to a second phase state or vice versa upon applying an electrical signal and may remain in the respective phase state for at least some time (referred to as retention time).

With reference to FIG. 1C, the memory cell 102 may include at least one capacitor (the SPOC structure 120) and a transistor (the FET structure 110) such that the memory cell 102 may be a one transistor, T, one capacitor, C, memory cell (1T1C cell). It is understood that this serves for illustration and that the memory cell 102 may include more than one capacitor, thus being a one transistor multiple capacitors memory cell (1TxC cell). Further, it is understood that this three-terminal 1T1C memory cell serves as an example and that the memory cell may also be a two-terminal memory cell including the one capacitor, C, coupled between the two terminals. In this case, the memory cell arrangement may, for example, include an access transistor coupled to a same control line of a plurality of two-terminal memory cells. A (e.g., non-volatile) ferroelectric random-access memory (FeRAM) may, for example, include a plurality of memory cells 102 configured to as 1TxC (with x≥1) memory cells. The node coupled between the FET structure 110 and the SPOC structure 120 may be referred to as storage node (SN) 130 or storage terminal.

To read the stored memory state of the SPOC structure 120, a read voltage is typically applied across the SPOC structure 120 that is sufficient to program a remanent state of the state-programmable memory element to a predefined state. This develops a charge, QSPOC, that depends on the programmed state before the read voltage was applied, where if the read-out operation caused the state-programmable memory element to switch to a new state (e.g., the predefined state is different from the previously programmed state), a larger charge (resulting from a dielectric charge of the memory element and a switching charge (also referred to as polarization charge) due to switching the memory (polarization) state) will be provided, whereas if the read operation caused the state-programmable memory element to be re-programmed to the same state (e.g., the predefined state is the same as the previously programmed state), little charge (resulting from a dielectric charge of the memory element) will be provided from the memory element.

According to various aspects, a memory device may include a memory cell arrangement including a plurality of memory cell and may include a controller (e.g., a memory controller) configured to operate (e.g., read and write) the plurality of memory cells.

It is noted that a memory cell arrangement is usually configured in a matrix-type arrangement, wherein columns and rows define the addressing of the memory cells according to the control lines connecting respectively subsets of memory cells of the memory cell arrangement along the rows and columns of the matrix-type arrangement. However, other arrangements may be suitable as well.

In general, a memory cell arrangement may include a plurality of (e.g., volatile or non-volatile) memory cells, which may be accessed individually or on groups via a corresponding addressing scheme. The matrix architecture may be, for example, referred to as “OR”, “AND”, “NOR”, or “NAND” architecture, depending on the way neighboring memory cells are connected to each other, i.e., depending on the way the terminals of neighboring memory cells are shared, but are not limited to these two types (another type is for example an “AND” architecture). For example, in a NAND architecture the memory cells may be organized in sectors (also referred to as blocks) of memory cells, wherein the memory cells are serially connected in a string (e.g., source and drain regions are shared by neighboring transistors), and the string is connected to a first control line and a second control line. For example, groups of memory cells in a NAND architecture may be connected in series with one another. In a NOR architecture the memory cells may be connected in parallel with one another. A NAND architecture may thus be more suited for serial access to data stored in the memory cells, whereas a NOR architecture may be more suited for random access to data stored in the memory cells.

The memory cell described herein (e.g., as part of a memory cell arrangement) may be used in connection with any type of suitable controller, e.g., a controller that may generate only two or only three different voltage levels for writing the memory cell (e.g., for writing one or more memory cells of a memory cell arrangement). However, in other aspects, more than four different voltage levels may be used for operating (e.g., for reading) the memory cell or for operating one or more memory cells of a memory cell arrangement.

According to various aspects, the memory cell described herein may be configured complementary metal oxide semiconductor (CMOS) compatible, e.g., including standard CMOS-materials only and may require no special integration considerations (e.g., no special thermal budget which may avoid diffusion and/or contamination during manufacturing). CMOS compatible spontaneously polarizable materials may be used to implement the one or more memory cell based on, for example, HfO₂ and/or ZrO₂. Doped HfO₂ (e.g., Si:HfO₂ or Al:HfO₂) or other suitable spontaneously-polarizable materials may allow for an integration of the spontaneously polarizable layer via known integration schemes.

According to various aspects, the controller may be configured to provide one or more sets of voltage levels to operate a memory cell arrangement (e.g., including a plurality of memory cells). According to various aspects, a writing operation may be provided based on only two voltage levels (e.g., a first supply voltage level VPP and a second supply voltage level VNN). In the case that the CMOS technology provides electrical access to the bulk, all bulks may be connected to VNN or a voltage significantly similar to VNN but such that no diode from bulk to any source/drain region is forward biased.

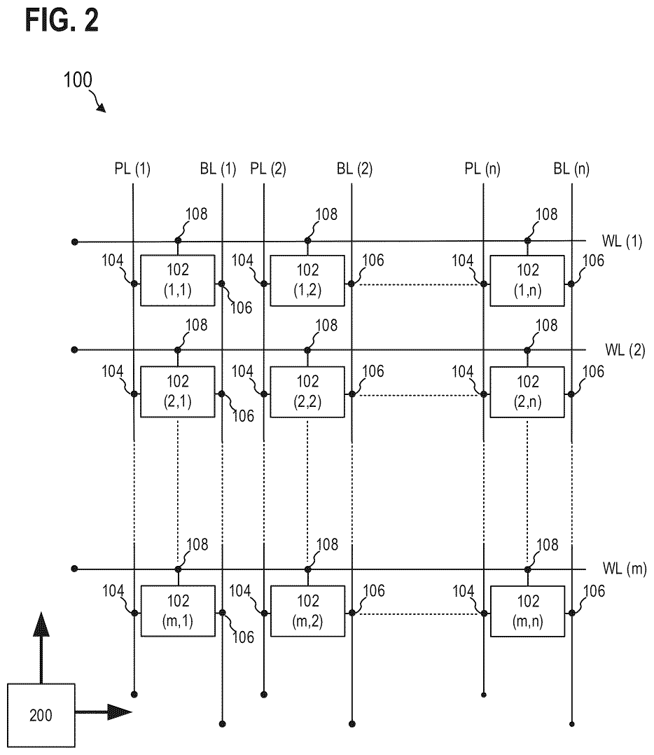

FIG. 2 shows an exemplary memory cell arrangement 100 including a plurality of memory cells 102(m=1 to M, n=1 to N). Each of the plurality of memory cells 102(m=1 to M, n=1 to N) may be configured according to the memory cell 102 described with reference to FIG. 1B or according to the memory cell 102 described with reference to FIG. 1C.

In the following, various aspects are detailed with reference to the memory cell arrangement 100. It is understood that the memory cell arrangement 100 serves as an exemplary memory cell arrangement to illustrate those aspects and that the memory cell arrangement may have any other suitable configuration.

The plurality of memory cells 102(m=1 to M, n=1 to N) may be arranged an array of N times M. “N” may be any integer number equal to or greater than one. “M” may be any integer number equal to or greater than one.

The memory cell arrangement 100 may include a plurality of bitlines BL(n=1 to N), a plurality of platelines PL(n=1 to N), and a plurality of wordlines WL(m=1 to M) for (individually and selectively) addressing the plurality of memory cells 102(m=1 to M, n=1 to N). Each memory cell 102(m*, n*) may be connected to and selectively (and individually) addressable via a corresponding bitline BL(n*) of the plurality of bitlines BL(n=1 to N), a corresponding wordline WL(m*) of the plurality of wordlines WL(m=1 to M), and a corresponding plateline PL(n*) of the plurality of platelines PL(n=1 to N). The *-notation may define one specific integer for the corresponding variable, such as a specific n* for the variable n, a specific m* for the variable m, etc.

The memory cell arrangement 100 may include a controller 200 (in some aspects referred to as control circuit). The controller 200 may be configured to apply a respective voltage to each control line described herein. The control controller 200 may be configured to apply a plateline voltage, V_{PL}, (via the corresponding plateline PL(n*)) at the first terminal 104, a bitline voltage, V_{BL}, (via the corresponding bitline BL(n*)) at the second terminal 106, and a wordline voltage, V_{WL}, (via the corresponding wordline WL(m*)) at the third terminal 108 of the memory cell 102(m*, n*) in order to address the memory cell 102(m*, n*). The controller 200 may be configured to carry out a write operation to write a memory state of at least one memory cell 102(m*, n*). The controller 200 (e.g., including a read-out circuit) may be configured to initiate (e.g., carry out) a read-out operation to read out the memory state of the at least one memory cell 102(m*, n*).

“Writing” a memory cell, as used herein, may be understood as bringing the memory cell into one of at least two different memory states. Writing a memory cell may also be referred to as programming the memory cell, wherein the memory state the memory cell is residing in after programming may be called “programmed state”. Therefore, the memory cell may also be referred to as state-programmable memory cell.

“Reading” a memory cell, as used herein, may be understood as determining the memory state the memory cell is residing in (e.g., programmed to). In general, a memory cell may be read either non-destructively (if the read-out operation does not change the memory state the memory cell is residing in) or destructively (if the read-out operation changes the memory state the memory cell is residing in). Thus, a destructive read-out operation may require a write operation subsequent to read-out in order to program again the memory state of the memory cell.

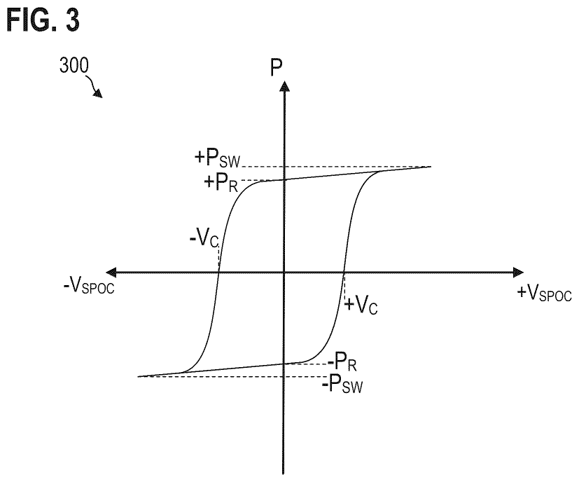

FIG. 3 shows a typical hysteresis curve (may also be referred to as polarization curve) 300 of a remanent-polarizable memory cell, where the polarization, P, is plotted as a function of the voltage, VSPOC, across the SPOC structure 120. The voltage, VSPOC, across the SPOC structure 120 may be a voltage difference between a voltage applied at the first terminal 104 (i.e., the plateline voltage VPL) and a voltage applied at the storage node 130. FIG. 3 shows the (capacitive) memory cell 102(m*, n*) exemplarily as a remanent-polarizable memory cell to illustrate various aspects thereof. The graph shows two remanent polarization states (+PR, −PR) of the memory element that may represent the programmable states of the memory element. For example, the memory cell 102(m*, n*) may be programmed to remanent polarization state +PR (representing, for example, a bit of digital information with a value of “0”) or to remanent polarization state-PR (representing, for example, a bit of digital information with a value of “1”), or vice versa, by applying a programming voltage across the SPOC structure 120 that is sufficient to program the corresponding remanent polarization state (e.g., via applying a plateline voltage VPL and a bitline voltage VBL). Therefore, the polarization curve 300 of the remanent-polarizable memory cell may also be referred to as memory window. The (positive) remanent polarization state +PR may be associated with a (negative) coercive voltage −VC (representing a corresponding (negative) electric field) and the (negative) remanent polarization state −PR may be associated with a (positive) coercive voltage +VC (representing a corresponding (positive) electric field). The coercive voltage ±VC may represent the voltage to depolarize the memory cell from its remanent polarization state ∓PR (viz. to bring the polarization P to zero). As shown, there may be a (maximum) positive switchable polarization +P_{SW} and a (maximum) negative switchable polarization +P_{SW}. The switchable polarization may also be referred to as switching polarization.

Various spontaneously-polarizable materials exhibit non-reliable polarization properties and/or polarization properties that are not suitable for operation in its as-formed condition (may also be referred to as as-grown condition), hence after being formed. It has been found that a preconditioning operation can modify the polarization properties of such as-formed spontaneously-polarizable materials to ensure stable polarization properties and to reduce voltage related requirements for the operation of the memory cell. Hence, the preconditioning operation may bring the spontaneously-polarizable material of a memory cell from an as-formed condition into an operable condition by improving the polarization properties. This behavior of such spontaneously-polarizable materials may also be referred to as “wake-up effect”.

An example of such a spontaneously-polarizable material is the ferroelectric hafnium zirconium oxide (Hf₁₋ₓZrₓO₂, HZO) described herein. In the case of HZO, the memory element may be formed by alternatingly forming hafnium oxide and zirconium oxide layers using atomic layer deposition (ALD). The material stack of the hafnium oxide and zirconium oxide layers may be substantially amorphous and may be subsequently crystallized by a thermal treatment (e.g., thermal annealing). Subsequently, the polarization properties of this crystalline memory element may be improved by the preconditioning operation. After this fabrication, the HZO may show suppressed ferroelectric properties. The full ferroelectric properties are achieved by the preconditioning operation 400.

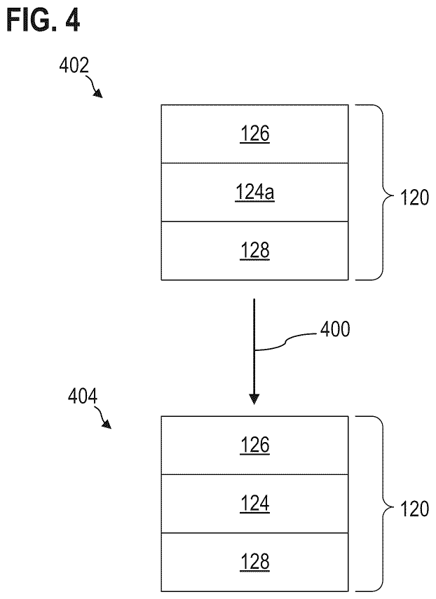

FIG. 4 schematically shows a preconditioning of the SPOC structure 120 according to various aspects. After being formed, the memory element 124a of the SPOC structure 120 may be in its as-formed condition 402 and the preconditioning operation 400 may bring the memory element 124 of the SPOC structure 120 into the operable condition 404.

It is understood that the preconditioning operation 400 may be carried out prior to the first use of the memory cell 102, for example prior to the first write operation carried out on the memory cell 102.

The preconditioning operation 400 may improve the polarization properties, for example, by ensuring a stable, reproducible, and predictable behavior of the polarization curve 300. The operable condition may be associated with one or more predefined polarization properties of the polarization curve 300, such as a predefined coercive voltage ±V_{C} and/or a predefined remanent polarization state ∓P_{R}.

For example, the preconditioning operation 400 may increase a value of the remanent polarization ∓P_{R} of the memory element. Thus, the memory element 124a may have a first remanent polarization value after being formed, viz. in its as-formed condition, and the preconditioning operation 400 may increase the remanent polarization from the first remanent polarization value to a second remanent polarization value (greater than the first remanent polarization value).

For example, the preconditioning operation 400 may reduce a value of the coercive voltage ±V_{C} of the memory element. Thus, the memory element 124a may have a first coercive voltage value after being formed, viz. in its as-formed condition, and the preconditioning operation 400 may reduce the coercive voltage from the first coercive voltage value to a second coercive voltage value (less than the first coercive voltage value).

The preconditioning operation 400 may reduce the voltage to be used for operating the memory cell(s) (e.g., may allow reducing the voltage to be used for endurance-testing of the memory cell(s)).

A preconditioning operation may also be referred to herein as precondition operation, preconditioning process, preconditioning cycle, or simply as preconditioning. The preconditioning operation being associated with a voltage signal may also be referred to as electrical conditioning operation or electrical conditioning procedure. Since the preconditioning operation initiates the wake-up of the memory cell(s), the preconditioning operation may also be referred to as wake-up operation, wake-up procedure, wakeup cycling, initialization procedure, initialization operation.

The preconditioning operation 400 allows to provide a controlled operable condition of the memory cell 102 rather than relying on the properties that the memory cell may have as-formed, thereby providing a more reliable and reproducible behavior of the memory cell 102, such as a more reliable and reproducible switching behavior of the polarization of the spontaneously-polarizable memory element 124.

As an example, the preconditioning may be carried out immediately after forming the memory cell (e.g., on a semiconductor substrate, for example on a die), for example during sorting (and prior to any other operation after sorting), so that the memory cell may be brought into the operable condition prior to any further operation. Sorting in a manufacturing process may be an inspection of a product (e.g., of the die(s)) to identify whether the product is non-functional. Sorting may be carried out prior to packaging (e.g., prior to packaging the die), so that only functional products are packaged (and delivered to a customer). For example, sorting may be or may include electrically testing the product, e.g., with a prober, to determine whether the electrical connections of the product are functioning correctly. Carrying out the preconditioning at sorting may provide delivering to a customer a memory cell being already in a (desired) operable condition, thus reducing the efforts for the customer. Optionally, there may be further testing of the plurality of memory cells after carrying out the preconditioning operation 400. The preconditioning operation 400 may reduce the requirements (e.g., required switching voltage(s)) of the testing. For example, the manufacturing may include an endurance test after carrying out the preconditioning operation 400. The endurance test may include testing the behavior of a (e.g., each) memory cell 102 under expected operating conditions. For example, the endurance test may include carrying out one or more write operations and/or one or more read operations of the memory cell 102, to verify the stability of the operation of the memory cell 102. The endurance test may provide determining whether the memory cell 102 is expected to function correctly over time. The previous preconditioning operation 400 may ensure that the endurance test may be carried out with reduced voltages (e.g., reduced write voltages and/or reduced readout voltages) with respect to an endurance test carried out on a memory cell with a non-preconditioned memory element. As an example, carrying out the endurance test may include providing one or more endurance voltage pulses at the memory cell 102 (to generate endurance voltage drops over the spontaneously-polarizable memory element), and the preconditioning operation 400 may allow using endurance voltage pulses having a reduced amplitude and/or a reduced duration with respect to an endurance test carried out on a memory cell with a non-preconditioned spontaneously-polarizable memory element. The preconditioning operation 400 may be carried out prior to packaging. Thus, during manufacturing, at least one die may include the plurality of memory cells and the preconditioning operation 400 may be carried out prior to packaging the die (e.g., to form (at least part of) a corresponding memory chip (e.g., of a memory device)). Packaging of the die including the memory cell arrangement 100 may include encapsulating the die, e.g., in an encapsulation structure that protects the die from external influences (e.g., corrosion, bumps, etc.). The packaging may be a wafer-level packaging or a panel-level packaging.

As another example, the preconditioning may be carried out prior to a first actual use of the memory cell, e.g., prior to storing any data into the memory cell (illustratively, prior to the first writing operation carried out on the memory cell).

Thus, the preconditioning operation 400 may be carried out as part of the overall manufacturing process of the memory cell arrangement 100 (e.g., of a memory device including the memory cell arrangement 100). Hence, in general, the preconditioning (viz. the preconditioning operation 400) may be carried out prior to a (first) write operation of any memory cell 102 of the plurality of memory cells of the memory cell arrangement 100.

According to various aspects, the (memory) controller 200 of the memory cell arrangement 100 may be configured to cause the preconditioning operation 400 detailed herein.

The controller 200 may be (pre)configured to cause the preconditioning operation 400 only once (e.g., prior to any write operation) (e.g., prior to packaging) (viz. only once over the lifetime of the memory device). The controller 200 may be (pre)configured to cause the preconditioning operation 400 at or prior to a first use of the memory device including the memory cell arrangement 100. In some aspects, the memory device may be provided (e.g., to a customer) without the plurality of memory cells having been preconditioned (during the overall manufacturing process) and the implementation of the preconditioning operation may be assigned to the controller 200 (e.g., after packaging, and after delivery). The controller 200 may be configured to cause the preconditioning operation at any suitable time point prior to the first use of the memory device. As an example, the controller 200 may be (pre)configured to cause the preconditioning operation 400 upon the first powering of the memory device. As another example, the controller 200 may be (pre)configured to cause the preconditioning operation 400 in response to the first received writing instructions to write data into the memory cell(s) 102. The controller 200 may be (pre)configured to cause the preconditioning operation independently of a writing operation of the at least one memory cell 102. Illustratively, the controller 200 may be (pre)configured to cause the preconditioning operation independently of whether the memory cell(s) 102 are about to be written. The decoupling of the preconditioning from the writing of the memory cell(s) 102 may allow making the memory cell(s) 102 ready in the operable condition at a convenient time point (e.g., when the memory device is powered but not being used), so that the operation of the memory device is not slowed down.

In some aspects, the controller 200 may be configured or instructed to cause a further preconditioning operation 400. The further preconditioning operation 400 may be, for example, instructed in the case that a malfunction or a non-desired operation of the memory device is detected. The controller 200 may be, for example, configured to cause the further preconditioning operation 400 at predefined time points (e.g., after one year of lifetime of the memory device, or after three years of lifetime of the memory device, as examples).

Herein, various aspects of the preconditioning operation 400 are detailed. It is understood that the controller 200, being configured to cause the preconditioning operation 400, may be configured to accordingly to cause the aspects of the preconditioning operation 400 detailed herein (e.g., to supply the periodic precondition signal 600).

The preconditioning operation 400 described herein may ensure an increased uniformity in the properties of the memory cells (e.g., in the properties of a memory device including one or more memory cells). Illustratively, carrying out a preconditioning operation may provide bringing the memory cells into a (respective) operable condition, thus reducing the effects of fabrication-induced variations in thew properties of the memory cells, e.g., in the properties of the respective spontaneously-polarizable memory element 124.

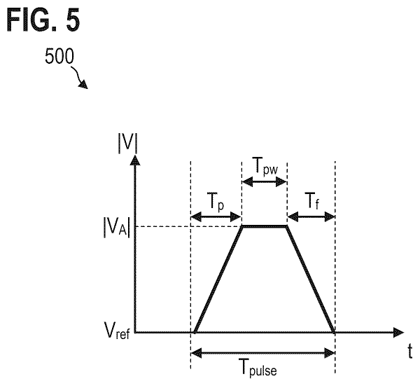

The preconditioning operation 400 may include applying a precondition signal at the memory cell 102. This precondition signal may include an alternating sequence of precondition voltage pulses of opposite polarities. FIG. 5 shows an exemplary precondition voltage pulse 500 according to various aspects.

The precondition voltage pulse 500 may include, within a rising time Tₚ, a rising flank associated with an increase of an absolute voltage value up to a voltage amplitude value, V_{A}. The rising time Tₚ, may be or may represent the amount of time the precondition voltage pulse 500 takes to go from the reference voltage, V_{ref}, to the voltage amplitude value, V_{A}. In various aspects, the rising time Tₚ, may be or may represent the amount of time the precondition voltage pulse 500 takes to go from a voltage level equal to about 10% of the voltage amplitude value, V_{A}, to a voltage level equal to about 90% of the voltage amplitude value, V_{A}. As a numerical example, the rising time Tₚ, may be in the range from about 1 ns to about 100 ns, for example from about 5 ns to about 50 ns

The voltage amplitude value, V_{A}, may be or may represent a maximum voltage value (or voltage level) associated with the precondition voltage pulse 500. Thus, the voltage amplitude value, V_{A}, may be or may represent the magnitude of a voltage level (e.g., a precondition voltage, Vp) associated with the precondition voltage pulse 500. Illustratively, the voltage amplitude value, V_{A}, may be or may represent a voltage level associated with the precondition voltage pulse 500 evaluated with respect to the reference voltage value, V_{ref}, (e.g., a base voltage, V_{B}, of a memory cell or of a memory device). The voltage amplitude value, V_{A}, may also be referred to as peak amplitude. The voltage amplitude value, V_{A}, may be different from (e.g., greater than) the amplitude of a write voltage pulse to write the memory cell 102, e.g., may be different from (e.g., greater than) a voltage provided by an operating circuit associated with the memory cell 102. In various aspects, the voltage amplitude value, V_{A}, may be greater than the amplitude of an endurance voltage pulse for endurance testing of the memory cell 102.

The voltage may be kept at the voltage amplitude value, V_{A}, for a predefined time period. This predefined time period may define the pulse width, T_{pw}. The pulse width, T_{pw}, may also be referred to as pulse duration, pulse width time, pulse duration time. Hence, the pulse width, T_{pw}, may be or may represent the amount of time during which the voltage amplitude value, V_{A}, of the precondition voltage pulse 500 is at its maximum value (e.g., the amount of time the peak amplitude of the precondition voltage pulse 500 is at the precondition voltage level). As a numerical example, the precondition voltage pulse 500 may have a pulse width, T_{pw}, in the range from about 10 ns to about 2 s, for example from about 100 ns to about 1500 ms, for example from about 500 ns to about 1 ms. In various aspects, the pulse width, T_{pw}, may be different from (e.g., greater than) the pulse width of a write voltage pulse to write the memory cell 102, e.g., may be different from (e.g., greater than) the pulse width of a voltage pulse provided by an operating circuit associated with the memory cell. In various aspects, the pulse width, T_{pw}, may be greater than the pulse width of an endurance voltage pulse for endurance testing of the memory cell 102.

The precondition voltage pulse 500 may include, within a falling time T_{f}, a falling flank associated with a decrease of the absolute voltage value from the voltage amplitude value, V_{A}, to the reference voltage value, V_{ref}. In some aspects, the falling time T_{f} may be substantially the same as the rising time Tₚ. In other aspects, the falling time T_{f} and the rising time Tₚ may be different from one another.

According to various aspects, a total duration, Tₚᵤₗₛₑ, of the precondition voltage pulse 500 may be determined by the pulse width, T_{pw}, the rising time Tₚ, and the falling time T_{f} of the precondition voltage pulse 500.

As detailed herein, the precondition signal may include an alternating sequence of precondition voltage pulses of opposite polarities. Therefore, the precondition signal may also be referred to as bipolar (voltage) signal. Thus, it is understood that each first precondition (voltage) pulse of the precondition signal 600 is directly followed by a second precondition (voltage) pulse, and vice versa.

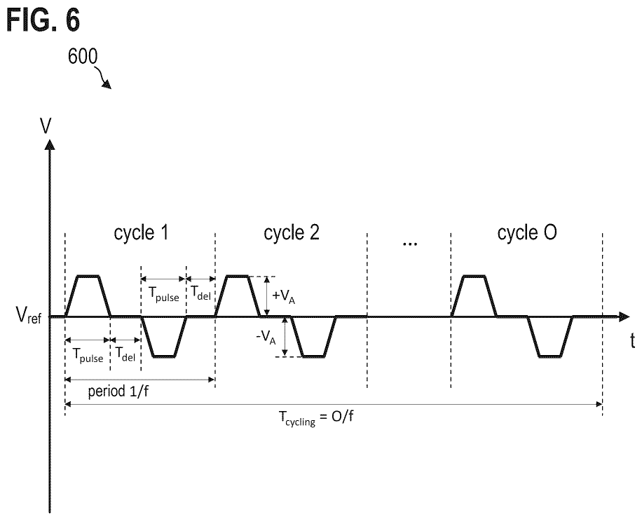

FIG. 6 shows various aspects of an exemplary precondition signal 600. The precondition signal 600 (being a voltage signal over time, t) may include a plurality of O (signal) cycles. “O” may be any integer number equal to or greater than two. Hence, the precondition signal 600 may be a periodic precondition signal 600. Each cycle, o, of the plurality of cycles, o=1 to O, may include a first (voltage) pulse having a first polarity (e.g., +V) and may include a second (voltage) pulse having a second polarity (e.g., −V, or vice versa) opposite to the first polarity. According to various aspects, each cycle may include exactly one first (voltage) pulse and exactly one second (voltage) pulse.

In some aspects, the pulse duration, Tₚᵤₗₛₑ, of the first (voltage) pulse and the pulse duration, Tₚᵤₗₛₑ, of the second (voltage) pulse may be substantially the same. In other aspects, there may be a first pulse duration, Tₚᵤₗₛₑ₁, of the first (voltage) pulse and a second pulse duration, Tₚᵤₗₛₑ₂, of the second (voltage) pulse different from the first pulse duration, Tₚᵤₗₛₑ₁.

In some aspects, the voltage amplitude value, |+V_{A}|, of the first (voltage) pulse and the voltage amplitude value, |−V_{A}|, of the second (voltage) pulse may be substantially the same. In other aspects, there may be a first voltage amplitude value, |+V_{A}|, of the first (voltage) pulse and a second voltage amplitude value, |−V_{A}|, of the second (voltage) pulse different from the first voltage amplitude value, |+V_{A}|.

Between two subsequent pulses of the precondition signal 600 there may be an off time or delay time, T_{del}, during which no voltage is applied. Hence, the delay time, T_{del}, may be a time period between two neighboring precondition voltage pulses. In some aspects, the delay time, T_{del}, after a first (voltage) pulse and prior to a second (voltage) pulse may be substantially the same as the delay time, T_{del}, after a second (voltage) pulse and prior to a first (voltage) pulse. In other aspects, there may be a first delay time, T_{del1}, after a first (voltage) pulse and prior to a second (voltage) pulse and there may be a second delay time, T_{del2}, different from the first delay time, T_{del1}, after a second (voltage) pulse and prior to a first (voltage) pulse.

A duty cycle may be the fraction of one cycle, o, in which a voltage is applied (viz. the precondition signal active). Thus, the duty cycle, DT, may be determined by:

$$DT = \frac{{T}_{pulse 1} + {T}_{pulse 2}}{{T}_{pulse 1} + {T}_{del 1} + {T}_{pulse 2} + {T}_{del 2}}$$

With Tₚᵤₗₛₑ₁=Tₚᵤₗₛₑ₂ and T_{del1}=T_{del2}, the duty cycle, DT, may be determined by:

$$DT = \frac{{T}_{pulse}}{{T}_{pulse} + {T}_{del}}$$

The duty cycle may be expressed as a ratio as given by above equations or as a percentage (by multiplying with 100%).

The term duty cycle may also be referred to as power cycle and/or duty factor.

The precondition signal 600 may have a predefined frequency, f. Hence, each cycle, o, may be associated with a period with a time duration of 1/f and a total cycling time, T_{cycling}, may be O/f.

Commonly, the fabrication of the spontaneously-polarizable material layers is adapting to aim for a reduced or even eliminated wake-up requirement. However, there are various spontaneously-polarizable materials for which the wake-up requirement cannot be eliminated.

Zhou et al.: “Wake-up effects in Si-doped hafnium oxide ferroelectric thin films”, Applied Physics Letters, Volume 103, Issue 19, 2013 (in the following referred to as reference [1]) describes that, in the case of ferroelectric hafnium oxide, a greater voltage amplitude value, V_{A}, can lead to a faster wake-up. However, reference [1] does not consider negative effects resulting thereof.

It has been found that increasing the voltage amplitude value, V_{A}, increases the generation of defects in the spontaneously-polarizable material of the memory element 124 and that these defects increase the switching voltage (viz, the voltage required for switching the memory cell 102 from one remanent state to another remanent state). The greater the switching voltage, the greater the energy consumption of the memory device.

Therefore, it may be desired to decrease the voltage amplitude value, V_{A}, which, however, results in an increase of the cycling time (viz, the wake-up time). Hence, there is a multi-dimensional problem.

According to various aspects, it has been found that this multi-dimensional problem without any trade-off, but by achieving both, less defects (and hence, a lower energy consumption) and a reduced cycling time (viz. a faster wake-up).

This is achieved by providing a precondition signal with a frequency equal to or less than 150 Hz, thereby allowing to precondition (viz. to wake-up) multiple (e.g., all) memory cells of the memory cell arrangement 100 in parallel. According to various aspects, the preconditioning operation even allows to achieve a greater switchable polarization as compared to greater frequencies (e.g., in the kHz range and above).

For example, the frequency of the precondition signal may be equal to or less than 110 Hz (e.g., about 100 Hz). According to various aspects, the frequency, f, of the precondition signal may fulfill the following requirement:

$$f < \frac{{I}_{max} - {I}_{leak} {N}_{cells}}{2 ( ( ‖ + {V}_{A} \vert - \vert - {V}_{A} ‖ ) \frac{{ε}_{SP}}{{t}_{SP}} + 2 {P}_{SW} ) {A}_{cell} {N}_{cells}}$$

N_{cells} may be the number of memory cells of the memory cell arrangement 100 (e.g., N_{cells}=N*M). The SPOC structure 120 (viz, the capacitive structure) of each memory cell 102 may have an area of A_{cell}. Iₘₐₓ may be a maximum power supply current applied to the memory cell arrangement 100 (e.g., a maximum power supply current applied to a memory circuit (e.g., memory chip) including the memory cell arrangement 100) during the precondition operation 400. Iₗₑₐₖ may be a leakage current per memory cell 102. t_{SP} may be a thickness of the memory element 124.

Above requirement considers that the frequency is limited by the RC time constant (may also be referred to as RC delay).

It has been found that, when fulfilling this requirement, all memory cells of the memory cell arrangement 100 can be preconditioned in parallel. With this the frequency, f, is in general equal to or less than 150 Hz and in many cases even less than 110 Hz.

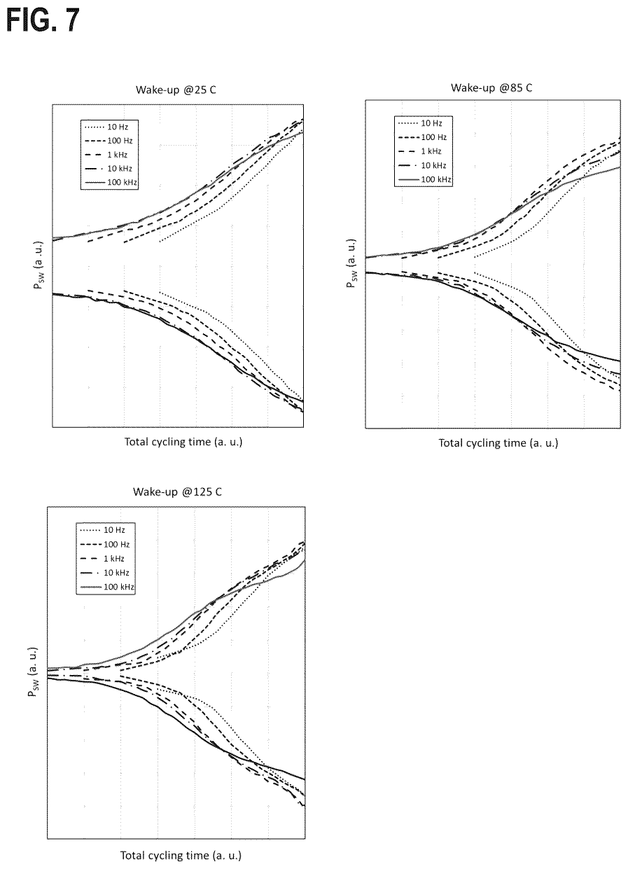

FIG. 7 shows the switchable polarization, P_{SW}, as a function of the (total) cycling time, T_{cycling}, for different frequencies of the precondition signal and for different temperatures according to various aspects. As shown, with increasing temperature, the initial suppression of the polarization is more severe, but the increase of the switchable polarization, P_{SW}, with the cycling time, T_{cycling}, is also faster. As shown, the respective slope of the curves increases with increasing temperature. The diagrams further show that reducing the frequency allows to achieve a greater switchable polarization, P_{SW}, when using a longer cycling time, T_{cycling}.

According to various aspects, the preconditioning operation 400 may include that the memory cell arrangement 100 is heated to a preconditioning temperature that is greater than a temperature during operation. This allows to reduce the cycling time, T_{cycling}.

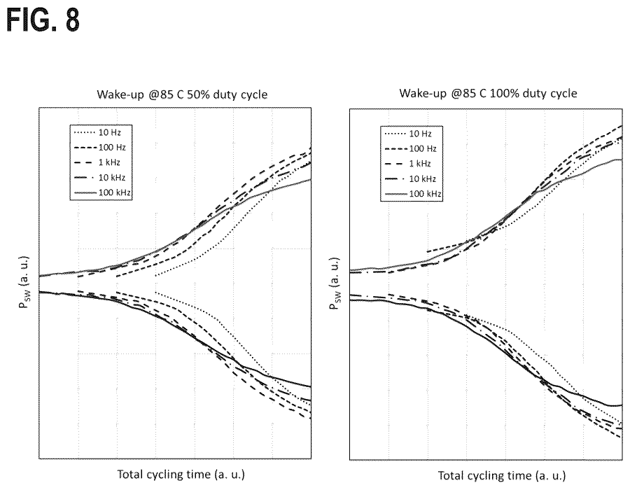

FIG. 8 shows the switchable polarization, P_{SW}, as a function of the (total) cycling time, T_{cycling}, for different frequencies of the precondition signal and for different duty cycles according to various aspects. As illustratively shown, when using a frequency, f, of about 100 Hz, the switchable polarization, P_{SW}, can be increased significantly as compared to higher frequencies. As illustratively shown, the respective slope of the curves increases with increasing duty cycle. However, the diagrams of FIG. 8 further show that the achieved switchable polarization, P_{SW}, of the 10 Hz precondition signal is less than that of the 100 Hz precondition signal. Therefore, according to various aspects, the frequency of the precondition signal may be in a range from about 50 Hz to about 150 Hz (e.g., in a range from about 80 Hz to about 110 Hz). It has been found that, when using the frequency in a range from about 50 Hz to about 150 Hz, the duty cycle, DT, equal to or greater than 90% leads to the greatest switchable polarization, P_{SW}. It has been found that a frequency a range from about 80 Hz to about 110 Hz in combination with a duty cycle of substantially 100% results in the greatest achievable switchable polarization, P_{SW}. Therefore, according to various aspects, the frequency may be in a range from about 80 Hz to about 110 Hz and the duty cycle may be substantially 100%.

However, increasing the switchable polarization, P_{SW}, is not the only figure of merit for device performance. It has been found that the preconditioning operation 400 can also reduce the power consumption of the memory device in operation by reducing the switching voltage thereof. This is achieved by limiting the voltage amplitude of the precondition signal.

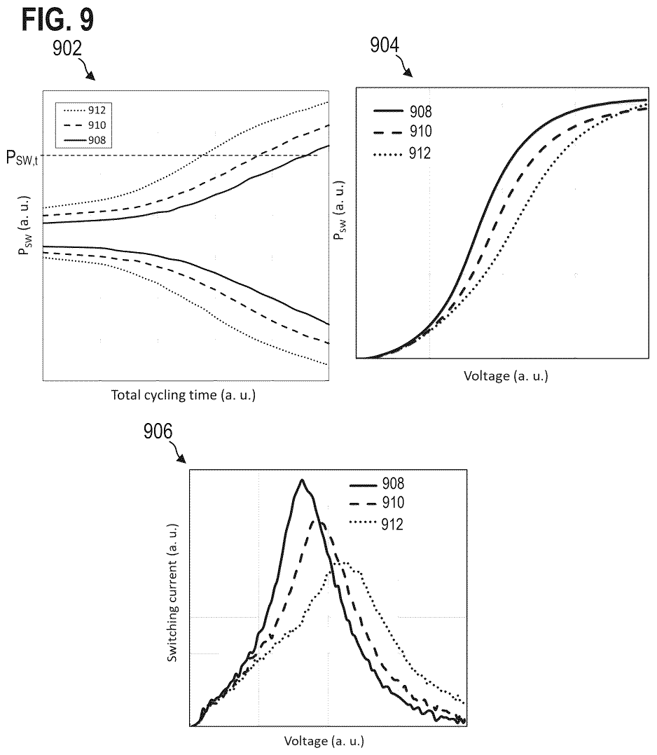

FIG. 9 shows various aspects of the switchable polarization, P_{SW}, for different voltage amplitudes, V_{A}, of the precondition signal according to various aspects.

The diagrams 902, 904, and 906 each show curves for a high voltage amplitude value 912 (e.g., of +V_{A}=3.0V and −V_{A}=−2.5V), for a medium voltage amplitude value 910 (e.g., of +V_{A}=2.5V and −V_{A}=−2.0V), and for a low voltage amplitude value 908 (e.g., of +V_{A}=2.0V and −V_{A}=−2.0V). The diagrams 902, 904, and 906 refer to a duty cycle of 100%.

Diagram 902 shows that with decreasing voltage amplitude value the (total) cycling time, T_{cycling}, is increased. However, a target switchable polarization, P_{SW,t}, may still be achievable (by increasing the total cycling time). This may be guaranteed by using the duty cycle equal to or greater than 90%. As detailed herein, such a duty cycle would, by its own, increase the slope of the switchable polarization, P_{SW}, over cycling time, T_{cycling}, curve. This increased slope may then allow to achieve the target switchable polarization even when using the low voltage amplitude value 908.

Diagram 904 shows that reducing the voltage amplitude value allows to switch the memory element 124 at lower switching voltages, thereby reducing the power consumption of the memory device after the preconditioning operation 400. Diagram 906 shows the corresponding switching current. It has been found that the switching voltage can be reduced since reducing the voltage amplitude results in a reduced defect generation within the spontaneously-polarizable material of the memory element 124. Further, in addition to the power consumption, the reduced switching voltage also reduces the probability of a device failure, thereby increasing reliability of the memory device.

Illustratively, using the frequency, f, in the range detailed herein allows to precondition the memory cells in parallel. The duty cycle equal to or greater than 90% allows to increase the slope of the switchable polarization, P_{SW}, over cycling time, T_{cycling}, curve to allow to use the low voltage amplitude value 908. According to various aspects, the absolute value of this low voltage amplitude value 908 (viz. ±V_{A}) may be equal to or less than 2.0 V. According to various aspects, the absolute value of the voltage amplitude value, |+V_{A}|, of the first (voltage) pulse and the absolute value of the voltage amplitude value, |−V_{A}|, of the second (voltage) pulse may be less than

$$\vert \pm {V}_{A} \vert < \frac{1}{2} {E}_{BD} {t}_{SP} ( viz . \vert \pm {V}_{A} \vert < \frac{1}{2} {E}_{BD} {t}_{SP} ) .$$

E_{BD} may be the breakdown field-strength of the memory element 124.

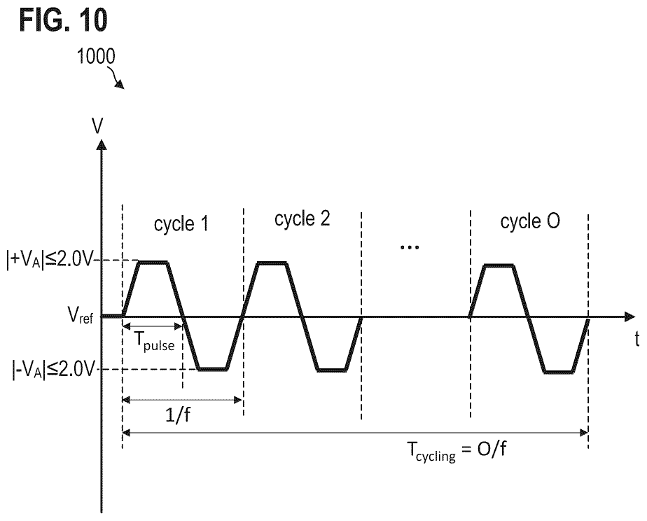

FIG. 10 shows an exemplary precondition signal 1000 according to various aspects. The precondition signal 1000 may have the frequency, f, in the range from about 80 Hz to about 110 Hz and the duty cycle, DT, of 100%. This duty cycle of 100% allows to use a positive and negative voltage amplitude that has an absolute value equal to or less than 2.0 V. This absolute value of equal to or less than 2.0 V allows to significantly reduce the switching voltage of each memory cell 102, thereby decreasing the power consumption of the memory device and the reliability of each memory cell 102.

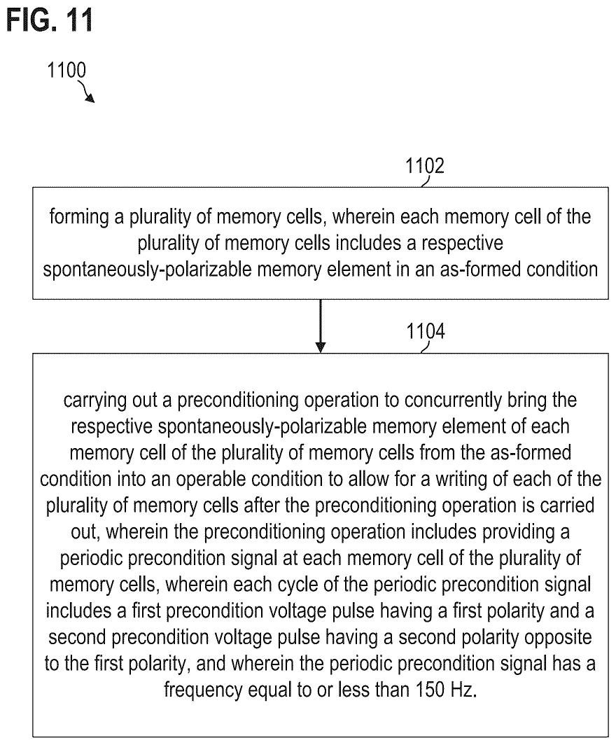

FIG. 11 shows a flow diagram of a method 1100 for manufacturing a memory cell arrangement (e.g., the memory cell arrangement 100).

The method 1100 may include (in 1102) forming a plurality of memory cells. Each memory cell of the plurality of memory cells may include a respective spontaneously-polarizable (e.g., remanent-polarizable) memory element in an as-formed condition.

The method 1100 may include (in 1104) carrying out a preconditioning operation to concurrently (e.g., simultaneously, hence in parallel) bring the respective spontaneously-polarizable memory element of each memory cell of the plurality of memory cells from the as-formed condition into an operable condition to allow for a writing of each of the plurality of memory cells after the preconditioning operation is carried out. The preconditioning operation may include providing (e.g., applying) a periodic precondition signal at each memory cell of the plurality of memory cells (to cause an alternating sequence of voltage drops of opposite polarities over the respective spontaneously-polarizable memory element). Each cycle of the periodic precondition signal may include a first precondition voltage pulse having a first polarity and a second precondition voltage pulse having a second polarity opposite to the first polarity. The periodic precondition signal may have a frequency equal to or less than 150 Hz (e.g., equal to or less than 110 Hz).

The preconditioning operation may be configured as detailed herein (e.g., with reference to the preconditioning operation 400).

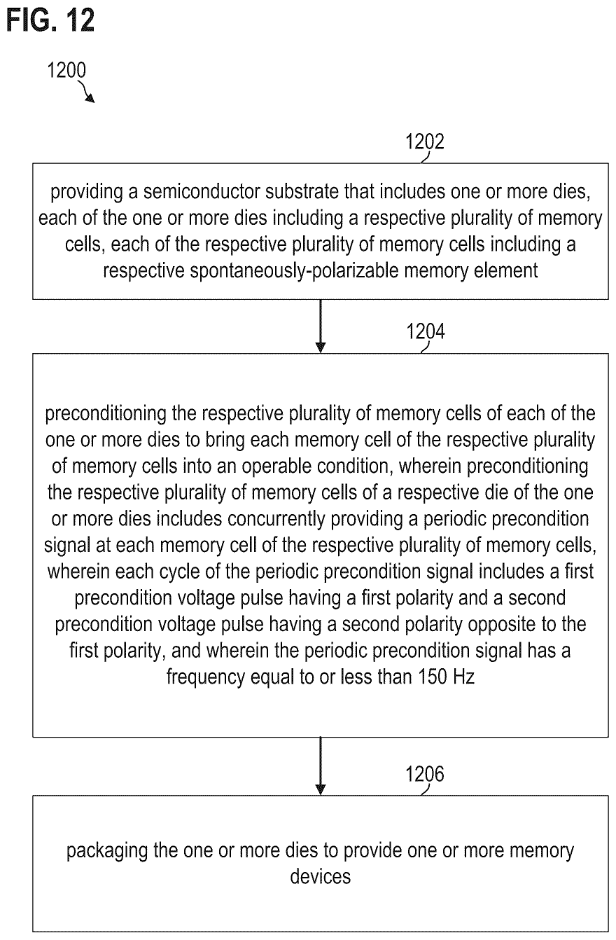

FIG. 12 shows a flow diagram of a method 1200 for manufacturing one or more memory devices (e.g., including the memory cell arrangement 100).

The method 1200 may include (in 1202) providing a semiconductor substrate that includes one or more dies, each of the one or more dies including a respective plurality of memory cells, each of the respective plurality of memory cells including a respective spontaneously-polarizable (e.g., remanent-polarizable) memory element

The method 1200 may include (in 1206) preconditioning the respective plurality of memory cells of each of the one or more dies to bring each memory cell of the respective plurality of memory cells into an operable condition. The preconditioning the respective plurality of memory cells of a respective die of the one or more dies may include concurrently (e.g., simultaneously) providing (e.g., applying) a periodic precondition signal at each memory cell of the respective plurality of memory cells (to cause an alternating sequence of voltage drops of opposite polarities over the respective spontaneously-polarizable memory element). Each cycle of the periodic precondition signal may include a first precondition voltage pulse having a first polarity and a second precondition voltage pulse having a second polarity opposite to the first polarity. The periodic precondition signal may have a frequency equal to or less than 150 Hz (e.g., equal to or less than 110 Hz).

The preconditioning may be configured as detailed herein (e.g., with reference to the preconditioning operation 400).

The method 1200 may include (in 1206) packaging the one or more dies to provide one or more memory devices.

It is understood that the memory cell arrangement 100 serves as an example on which the preconditioning operation 400 detailed herein may be applied on. The preconditioning operation 400 described herein can be applied to any kind of device that includes a spontaneously-polarizable (e.g., ferroelectric) material, such as ferroelectric transducers, ferroelectric sensors, etc.

In the following, various examples are provided that may include one or more aspects described above with reference to a memory cell including the SPOC structure 120, to a memory cell arrangement including at least one such memory cell, and to the methods described herein. It may be intended that aspects described in relation to one or more of the methods may apply also to the memory cell and/or memory cell arrangement, and vice versa. For example, a method may include at least a part of the formation of the SPOC structure 120.

Example 1 is a method for manufacturing a memory cell arrangement (e.g., of a memory device), the method including forming a plurality of memory cells, wherein each memory cell of the plurality of memory cells includes a respective spontaneously-polarizable (e.g., remanent-polarizable) memory element in an as-formed condition; carrying out a preconditioning operation to concurrently (e.g., simultaneously, hence in parallel) bring the respective spontaneously-polarizable memory element of each memory cell of the plurality of memory cells from the as-formed condition into an operable condition to allow for a writing of each of the plurality of memory cells after the preconditioning operation is carried out; wherein the preconditioning operation includes providing (e.g., applying) a periodic precondition signal at each memory cell of the plurality of memory cells (to cause an alternating sequence of voltage drops of opposite polarities over the respective spontaneously-polarizable memory element), wherein each cycle of the periodic precondition signal includes a first precondition voltage pulse having a first polarity and a second precondition voltage pulse having a second polarity opposite to the first polarity, and wherein the periodic precondition signal has a frequency equal to or less than 150 Hz (e.g., equal to or less than 110 Hz).

Using the frequency equal to or less than 150 Hz allows to precondition (viz. to wake-up) multiple memory cells (e.g., all memory cells of a memory device or at least all memory cells of a same die) together (viz. in parallel), thereby reducing the total time required for preconditioning all memory cells of the memory device. Illustratively, the method allows for a more efficient preconditioning of the memory cells of a memory device.

In Example 2, the subject matter of Example 1 can optionally include that the precondition signal has a duty cycle equal to or greater than 90% (e.g., substantially 100%).

In general, using a comparatively low frequency of equal to or less than 150 Hz increases the cycling time required to achieve a target (e.g., desired) switchable polarization. However, it has been found that using the duty cycle equal to or greater than 90%, such as duty cycle of substantially 100%, allows to achieve the switchable polarization within the substantially same cycling time as compared to higher frequencies. It has been further found that, when using a frequency of about 100 Hz and a duty cycle of substantially 100%, an even higher switchable polarization can be achieved within the substantially same cycling time as compared to higher frequencies.

In Example 3, the subject matter of Example 1 or 2 can optionally include that an absolute value of a first amplitude of the first precondition voltage pulse is equal to or less than 2.5 V (e.g., equal to or less than 2.0 V); and wherein an absolute value of a second amplitude of the second precondition voltage pulse is equal to or less than 2.5 V (e.g., equal to or less than 2.0 V).

In Example 4, the subject matter of any one of Examples 1 to 3 can optionally include that an (e.g., the) absolute value of a first amplitude (+V_{A}) of the first precondition voltage pulse and an (e.g., the) absolute value of the second amplitude (−V_{A}) of the second precondition voltage pulse are less than half of a product of a breakdown field-strength (E_{BD}) of the respective spontaneously-polarizable memory element and a thickness (t_{SP}) of the respective spontaneously-polarizable memory element

$$( viz . \vert \pm {V}_{A} \vert < \frac{1}{2} {E}_{BD} {t}_{SP} ) .$$

With reference to Examples 3 and 4, it has been found that, although higher voltage amplitudes reduce the cycling time required to achieve the target switchable polarization, the higher voltage amplitudes may generate defects within the spontaneously-polarizable memory element material, thereby increasing the voltage required for switching the polarization (viz. the switching voltage). It has been found that reducing the voltage amplitudes as defined by Examples 3 and 4 allows to reduce the switching voltage, thereby reducing the power consumption of the memory device.

In Example 5, the subject matter of any one of Examples 1 to 4 can optionally include that the preconditioning operation further includes bringing (e.g., heating) the plurality of memory cells to a preconditioning temperature, the preconditioning temperate being greater than a temperature of the plurality of memory cells during operation (e.g., the preconditioning temperature may be equal to or greater than 85° C.).

Carrying out the preconditioning operation at elevated temperatures allows to reduce the cycling time required to achieve the target switchable polarization, thereby providing a more effective preconditioning.

In Example 6, the subject matter of any one of Examples 1 to 5 can optionally include that the frequency, f, of the precondition signal is less than:

$$\frac{{I}_{max} - {I}_{leak} {N}_{cells}}{2 ( ( ‖ + {V}_{A} \vert - \vert - {V}_{A} ‖ ) \frac{{ε}_{SP}}{{t}_{SP}} + 2 {P}_{SW} ) {A}_{cell} {N}_{cells}}$$

wherein the plurality of memory cells includes a number of N_{cells} memory cells; wherein each memory cell of the plurality of memory cells includes a respective spontaneously-polarizable capacitor structure having an area of A_{cell}, the respective spontaneously-polarizable capacitor structure including the respective spontaneously-polarizable memory element; wherein Iₘₐₓ is a maximum power supply current applied to the memory cell arrangement during the precondition operation, Iₗₑₐₖ is a leakage current per memory cell of the plurality of memory cells, +V_{A} is a voltage amplitude value of the first precondition voltage pulse, −V_{A} is a voltage amplitude value of the second precondition voltage pulse, ε_{SP} is a permittivity of the respective spontaneously-polarizable memory element, t_{SP} is a thickness of the respective spontaneously-polarizable memory element, and is P_{SW} a (maximum) switchable polarization of the respective spontaneously-polarizable memory element.

It has been found that above equations allows to determine the limit frequency that allows to precondition (viz. to wake-up) multiple memory cells in parallel.

In Example 7, the subject matter of any one of Examples 1 to 6 can optionally include that the respective spontaneously-polarizable memory element includes or consists of a spontaneously-polarizable material.

In Example 8, the subject matter of Example 7 can optionally include that the spontaneously-polarizable material includes or consists of a remanent-polarizable material (e.g., a ferroelectric material).

In Example 9, the subject matter of Example 7 or 8 can optionally include that the spontaneously-polarizable material is hafnium oxide, zirconium oxide, or hafnium zirconium oxide.

In Example 10, the subject matter of any one of Examples 1 to 9 can optionally include that the frequency is equal to or less than about 110 Hz (e.g., equal to 100 Hz); wherein the precondition signal has a duty cycle substantially equal to 100%; and wherein an absolute value of a first amplitude of the first precondition voltage pulse and an absolute value of a second amplitude of the second precondition voltage pulse are equal to about 2.0 V.

It has been found that these parameters (in particular when using a frequency of about 100 Hz) optimize the preconditioning in terms of required cycling time (by allowing to precondition multiple memory cells in parallel und still achieve the target switchable polarization without an increase of the cycling time, e.g., with an even reduced cycling time) and energy consumption of the memory device after preconditioning.

In Example 11, the subject matter of any one of Examples 1 to 10 can optionally include that a difference between an absolute value of a write voltage used for the writing of a respective memory cell of the plurality of memory cells after the preconditioning operation and an absolute value of a first amplitude of the first precondition voltage pulse is equal to or less than 0.5 V; and/or wherein a difference between an absolute value of the write voltage used for the writing of the respective memory cell of the plurality of memory cells after the preconditioning operation and an absolute value of a second amplitude of the second precondition voltage pulse is equal to or less than 0.5 V.

In Example 12, the subject matter of any one of Examples 1 to 11 can optionally include that the as-formed condition is a condition of the respective spontaneously-polarizable memory element of a respective memory cell of the plurality of memory cells after forming the spontaneously-polarizable memory element and prior to any cycling operation of the respective memory cell.

In Example 13, the subject matter of any one of Examples 1 to 12 can optionally include that the as-formed condition of the respective spontaneously-polarizable memory element is associated with an as-formed magnitude of a remanent polarization of the respective spontaneously-polarizable memory element; and wherein the operable condition of the respective spontaneously-polarizable memory element is associated with an operable magnitude of the remanent polarization of the respective spontaneously-polarizable memory element, the operable magnitude of the remanent polarization being greater than the as-formed magnitude.

In Example 14, the subject matter of any one of Examples 1 to 13 can optionally include that the as-formed condition of the respective spontaneously-polarizable memory element of a respective memory cell of the plurality of memory cells is associated with an as-formed write voltage value for writing the respective memory cell into a memory state of at least two memory states; wherein the operable condition of the respective spontaneously-polarizable memory element of the respective memory cell is associated with an operable write voltage value for writing the respective memory cell into the memory state, the operable write voltage value being less than the as-formed write voltage value.

In Example 15, the method of any one of Examples 1 to 14 can optionally further include: after carrying out the preconditioning operation, carrying out an endurance test of each memory cell of the plurality of memory cells.

In Example 16, the subject matter of Example 15 can optionally include that carrying out the endurance test of a respective memory cell of the plurality of memory cells includes providing one or more endurance voltage pulses at the respective memory cell, wherein each of the one or more endurance voltage pulses has an endurance pulse width less than a first pulse width of the first precondition voltage pulse and less than a second pulse width of the second precondition voltage pulse.

In Example 17, the subject matter of any one of Examples 1 to 16 can optionally include that forming the plurality of memory cells includes forming the plurality of memory cells on a die of a semiconductor substrate; wherein the method further includes packaging the die after the preconditioning operation is carried out.

In Example 18, the method of any one of Examples 1 to 17 can optionally further include: during or prior to carrying out the preconditioning operation, carrying out a sorting of the plurality of memory cells.

In Example 19, the subject matter of any one of Examples 1 to 18 can optionally include that the preconditioning operation is carried out prior to a write operation of any memory cell of the plurality of memory cells.

Example 20 is a method of manufacturing one or more memory devices, the method including: providing a semiconductor substrate that includes one or more dies, each of the one or more dies including a respective plurality of memory cells, each of the respective plurality of memory cells including a respective spontaneously-polarizable (e.g., remanent-polarizable) memory element, and preconditioning the respective plurality of memory cells of each of the one or more dies to bring each memory cell of the respective plurality of memory cells into an operable condition, wherein preconditioning the respective plurality of memory cells of a respective die of the one or more dies includes concurrently (e.g., simultaneously) providing (e.g., applying) a periodic precondition signal at each memory cell of the respective plurality of memory cells (to cause an alternating sequence of voltage drops of opposite polarities over the respective spontaneously-polarizable memory element), wherein each cycle of the periodic precondition signal includes a first precondition voltage pulse having a first polarity and a second precondition voltage pulse having a second polarity opposite to the first polarity, and wherein the periodic precondition signal has a frequency equal to or less than 150 Hz (e.g., equal to or less than 110 Hz); and packaging the one or more dies to provide one or more memory devices.

In Example 21, the subject matter of Example 20 can optionally include that the precondition signal is provided concurrently (e.g., simultaneously) to the respective plurality of memory cells of each die of the one or more dies.

In Example 22, the subject matter of Example 20 or 21 can optionally include that the precondition signal has a duty cycle equal to or greater than 90% (e.g., substantially 100%).

In Example 23, the subject matter of any one of Examples 20 to 22 can optionally include that an absolute value of a first amplitude of the first precondition voltage pulse is equal to or less than 2.5 V (e.g., equal to or less than 2.0 V); and wherein an absolute value of a second amplitude of the second precondition voltage pulse is equal to or less than 2.5 V (e.g., equal to or less than 2.0 V).

In Example 24, the subject matter of any one of Examples 20 to 23 can optionally include that an absolute value of a first amplitude (+V_{A}) of the first precondition voltage pulse and an absolute value of a second amplitude (−V_{A}) of the second precondition voltage pulse are less than half of a product of a breakdown field-strength (E_{BD}) of the respective spontaneously-polarizable memory element and a thickness (t_{SP}) of the respective spontaneously-polarizable memory element

$$( viz . \vert \pm {V}_{A} \vert < \frac{1}{2} {E}_{BD} {t}_{SP} ) .$$

In Example 25, the subject matter of any one of Examples 20 to 24 can optionally include that the preconditioning further includes bringing (e.g., heating) the respective plurality of memory cells to a preconditioning temperature, the preconditioning temperate being greater than a temperature of the respective plurality of memory cells during operation (e.g., the preconditioning temperature may be equal to or greater than 85° C.).

In Example 26, the subject matter of any one of Examples 20 to 25 can optionally include that the frequency, f, of the precondition signal is less than:

$$\frac{{I}_{max} - {I}_{leak} {N}_{cells}}{2 ( ( ‖ + {V}_{A} \vert - \vert - {V}_{A} ‖ ) \frac{{ε}_{SP}}{{t}_{SP}} + 2 {P}_{SW} ) {A}_{cell} {N}_{cells}}$$

wherein the plurality of memory cells includes a number of N_{cells} memory cells; wherein each memory cell of the plurality of memory cells includes a respective spontaneously-polarizable capacitor structure having an area of A_{cell}, the respective spontaneously-polarizable capacitor structure including the respective spontaneously-polarizable memory element; wherein Iₘₐₓ is a maximum power supply current applied to the memory cell arrangement during the precondition operation, Iₗₑₐₖ is a leakage current per memory cell of the plurality of memory cells, +V_{A} is a voltage amplitude value of the first precondition voltage pulse, −V_{A} is a voltage amplitude value of the second precondition voltage pulse, ε_{SP} is a permittivity of the respective spontaneously-polarizable memory element, tsp is a thickness of the respective spontaneously-polarizable memory element, and is P_{SW} a (maximum) switchable polarization of the respective spontaneously-polarizable memory element.

In Example 27, the subject matter of any one of Examples 20 to 26 can optionally include that the respective spontaneously-polarizable memory element includes or consists of a spontaneously-polarizable material.

In Example 28, the subject matter of Example 27 can optionally include that the spontaneously-polarizable material includes or consists of a remanent-polarizable material (e.g., a ferroelectric material).

In Example 29, the subject matter of Example 27 or 28 can optionally include that the spontaneously-polarizable material is hafnium oxide, zirconium oxide, or hafnium zirconium oxide.

In Example 30, the subject matter of any one of Examples 20 to 29 can optionally include that the frequency is equal to or less than 100 Hz; wherein the precondition signal has a duty cycle substantially equal to 100%; and wherein an absolute value of a first amplitude of the first precondition voltage pulse and an absolute value of a second amplitude of the second precondition voltage pulse are equal to about 2.0 V.

In Example 31, the subject matter of any one of Examples 20 to 30 can optionally include that a difference between an absolute value of a write voltage used for the writing of a respective memory cell of the respective plurality of memory cells after the preconditioning and an absolute value of a first amplitude of the first precondition voltage pulse is equal to or less than 0.5 V; and/or wherein a difference between an absolute value of the write voltage used for the writing of the respective memory cell of the respective plurality of memory cells after the preconditioning and an absolute value of a second amplitude of the second precondition voltage pulse is equal to or less than 0.5 V.

In Example 32, the subject matter of any one of Examples 1 to 31 can optionally include that the respective spontaneously-polarizable memory element has an as-formed magnitude of a remanent polarization of the respective spontaneously-polarizable memory element prior to the preconditioning; and wherein the operable condition of the respective spontaneously-polarizable memory element is associated with an operable magnitude of the remanent polarization of the respective spontaneously-polarizable memory element, the operable magnitude of the remanent polarization being greater than the as-formed magnitude.

In Example 33, the subject matter of any one of Examples 20 to 32 can optionally include that the as-formed condition of the respective spontaneously-polarizable memory element of a respective memory cell of the plurality of memory cells is associated with an as-formed write voltage value for writing the respective memory cell into a memory state of at least two memory states; wherein the operable condition of the respective spontaneously-polarizable memory element of the respective memory cell is associated with an operable write voltage value for writing the respective memory cell into the memory state, the operable write voltage value being less than the as-formed write voltage value.

In Example 34, the method of any one of Examples 20 to 33 can optionally further include: after carrying out the preconditioning, carrying out an endurance test of each memory cell of the respective plurality of memory cells.

In Example 35, the subject matter of Example 34 can optionally include that carrying out the endurance test of a respective memory cell of the respective plurality of memory cells includes providing one or more endurance voltage pulses at the respective memory cell, wherein each of the one or more endurance voltage pulses has an endurance pulse width less than a first pulse width of the first precondition voltage pulse and less than a second pulse width of the second precondition voltage pulse.

In Example 36, the method of any one of Examples 20 to 35 can optionally further include: during or prior to carrying out the preconditioning, carrying out a sorting of the respective plurality of memory cells.

Example 37 is a memory device including: a plurality of memory cells, wherein each memory cell of the plurality of memory cells includes a respective spontaneously-polarizable (e.g., remanent-polarizable) memory element; a control circuit configured to cause a preconditioning operation to concurrently (e.g., simultaneously) bring the respective spontaneously-polarizable memory element of each memory cell of the plurality of memory cells from an as-formed condition into an operable condition to allow for a writing of each of the plurality of memory cells after the preconditioning is carried out; wherein the preconditioning operation includes providing (e.g., applying) a periodic precondition signal at each memory cell of the plurality of memory cells (to cause an alternating sequence of voltage drops of opposite polarities over the respective spontaneously-polarizable memory element), wherein each cycle of the periodic precondition signal includes a first precondition voltage pulse having a first polarity and a second precondition voltage pulse having a second polarity opposite to the first polarity, and wherein the periodic precondition signal has a frequency equal to or less than 150 Hz (e.g., equal to or less than 110 Hz).

In Example 38, the subject matter of Example 37 can optionally include that the memory device is not packaged.

In Example 39, the subject matter of Example 37 or 38 can optionally include that the control circuit is (pre)configured to cause the preconditioning operation only once.

In Example 40, the subject matter of any one of Examples 37 to 39 can optionally include that the precondition signal has a duty cycle equal to or greater than 90% (e.g., substantially 100%).

In Example 41, the subject matter of any one of Examples 37 to 40 can optionally include that an absolute value of a first amplitude of the first precondition voltage pulse is equal to or less than 2.5 V (e.g., equal to or less than 2.0 V); and wherein an absolute value of a second amplitude of the second precondition voltage pulse is equal to or less than 2.5 V (e.g., equal to or less than 2.0 V).

In Example 42, the subject matter of any one of Examples 37 to 41 can optionally include that an absolute value of a first amplitude (+V_{A}) of the first precondition voltage pulse and an absolute value of a second amplitude (−V_{A}) of the second precondition voltage pulse are less than half of a product of a breakdown field-strength (E_{BD}) of the respective spontaneously-polarizable memory element and a thickness (t_{SP}) of the respective spontaneously-polarizable memory element

$$( viz . \vert \pm {V}_{A} \vert < \frac{1}{2} {E}_{BD} {t}_{SP} ) .$$

In Example 43, the subject matter of any one of Examples 37 to 42 can optionally include that the control circuit is further configured to preconditioning operation further to bring (e.g., heat) the plurality of memory cells to a preconditioning temperature prior to providing the preconditioning signal, the preconditioning temperate being greater than a temperature of the plurality of memory cells during operation (e.g., the preconditioning temperature may be equal to or greater than 85° C.).

In Example 44, the subject matter of any one of Examples 37 to 43 can optionally include that the frequency, f, of the precondition signal is less than:

$$\frac{{I}_{max} - {I}_{leak} {N}_{cells}}{2 ( ( ‖ + {V}_{A} \vert - \vert - {V}_{A} ‖ ) \frac{{ε}_{SP}}{{t}_{SP}} + 2 {P}_{SW} ) {A}_{cell} {N}_{cells}}$$

wherein the plurality of memory cells includes a number of N_{cells} memory cells; wherein each memory cell of the plurality of memory cells includes a respective spontaneously-polarizable capacitor structure having an area of A_{cell}, the respective spontaneously-polarizable capacitor structure including the respective spontaneously-polarizable memory element; wherein Iₘₐₓ is a maximum power supply current applied to the memory cell arrangement during the precondition operation, Iₗₑₐₖ is a leakage current per memory cell of the plurality of memory cells, +V_{A} is a voltage amplitude value of the first precondition voltage pulse, −V_{A} is a voltage amplitude value of the second precondition voltage pulse, ε_{SP} is a permittivity of the respective spontaneously-polarizable memory element, tsp is a thickness of the respective spontaneously-polarizable memory element, and is P_{SW} a (maximum) switchable polarization of the respective spontaneously-polarizable memory element.

In Example 45, the subject matter of any one of Examples 37 to 44 can optionally include that the respective spontaneously-polarizable memory element includes or consists of a spontaneously-polarizable material.

In Example 46, the subject matter of Example 45 can optionally include that the spontaneously-polarizable material includes or consists of a remanent-polarizable material (e.g., a ferroelectric material).

In Example 47, the subject matter of Example 45 or 46 can optionally include that the spontaneously-polarizable material is hafnium oxide, zirconium oxide, or hafnium zirconium oxide.

In Example 48, the subject matter of any one of Examples 37 to 47 can optionally include that the frequency is equal to or less than 100 Hz; wherein the precondition signal has a duty cycle substantially equal to 100%; and wherein an absolute value of a first amplitude of the first precondition voltage pulse and an absolute value of a second amplitude of the second precondition voltage pulse are equal to about 2.0 V.

In Example 49, the subject matter of any one of Examples 37 to 48 can optionally include that the control circuit is configured to cause the preconditioning operation independently of a write operation for writing a respective memory cell of the plurality of memory cells into a memory state of at least two memory states.

In Example 50, the subject matter of Example 49 can optionally include that the write operation is associated with a write voltage; and wherein: a difference between an absolute value of the write voltage and an absolute value of a first amplitude of the first precondition voltage pulse is equal to or less than 0.5 V, and/or a difference between the absolute value of the write voltage and an absolute value of a second amplitude of the second precondition voltage pulse is equal to or less than 0.5 V.

In Example 51, the subject matter of Example 49 or 50 can optionally include that the as-formed condition of the respective spontaneously-polarizable memory element of a respective memory cell of the plurality of memory cells is associated with an as-formed write voltage for writing the respective memory cell into a memory state of the at least two memory states; and wherein an absolute value of the write voltage is less than an absolute value of the as-formed write voltage.

In Example 52, the subject matter of any one of Examples 37 to 51 can optionally include that the as-formed condition is a condition of the respective spontaneously-polarizable memory element prior to carrying out preconditioning operation even once.

In Example 53, the subject matter of any one of Examples 37 to 52 can optionally include that the as-formed condition of the respective spontaneously-polarizable memory element is associated with an as-formed magnitude of a remanent polarization of the respective spontaneously-polarizable memory element; and wherein the operable condition of the respective spontaneously-polarizable memory element is associated with an operable magnitude of the remanent polarization of the respective spontaneously-polarizable memory element, the operable magnitude of the remanent polarization being greater than the as-formed magnitude.

Several aspects are described with reference to a structure (e.g., a memory transistor structure, a field-effect transistor based memory structure, such as a ferroelectric field-effect transistor based memory structure, a capacitor-based memory structure (e.g., including one or more capacitors), such as a 1C (one capacitor) memory cell or a 1C1T (one capacitor and one transistor) memory cell (wherein the transistor in a 1C1T memory cell is an access transistor) and it is noted that such a structure may include solely the respective element (e.g., a memory transistor, a field-effect transistor, a ferroelectric field-effect transistor, a capacitive memory); or, in other aspects, a structure may include the respective element and one or more additional elements.

The term “operable” may be used herein in relation to a condition or to one or more properties, e.g., of a memory cell or a spontaneously-polarizable memory element, to include, for example, a desired condition or a desired value for a particular property that provide a stable operation of a memory cell. As an example, an operable condition of a memory cell may be a condition in which the memory cell may provide better performances (e.g., in terms of failures associated with the operation of the memory cell), e.g., may provide a reliable writing operation. As another example, a spontaneously-polarizable memory element being in an operable condition may have predefined properties or a predefined value of a particular property (e.g., a predefined remanent polarization, a predefined memory window, and/or the like) to provide better performances with respect to a spontaneously-polarizable memory element having non-predefined properties or a non-predefined value of a particular property. It is understood that a memory cell or a spontaneously-polarizable memory element, for example, may have more than one operable condition. For example, a memory cell or a spontaneously-polarizable memory element may have a plurality of operable conditions that ensure in a same or similar manner better performances with respect to other non-predefined conditions.

The term “as-formed” may be used herein in relation to a condition or to one or more properties, e.g., of a memory cell or a spontaneously-polarizable memory element, to include, for example, a condition or property being present (immediately) after forming the memory cell or (immediately) after forming the spontaneously-polarizable memory element. Illustratively, an as-formed condition or property may describe a memory cell or spontaneously-polarizable memory element as it/they come(s) out of a fabrication process (e.g., layer deposition and patterning). An as-formed property and/or an as-formed value of a property may be different from a property and/or from a value of a property in an operable condition. An as-formed condition or as-formed property may describe a memory cell or spontaneously-polarizable memory element prior to any intentional adaptation of the properties (e.g., of the polarization properties) of the memory cell or spontaneously-polarizable memory element, e.g., prior to subjecting the memory cell or spontaneously-polarizable memory element to any cycling operation (e.g., wake-up, endurance, writing, etc.). An as-formed condition may also be referred to herein as pristine condition or unadulterated condition. An as-formed property may also be referred to herein as pristine property or unadulterated property. Illustratively a “pristine memory cell” or a “pristine memory element” may describe a memory cell or memory element prior to any operation, e.g., prior to endurance testing, prior to writing, prior to readout, etc. A “pristine memory cell” or a “pristine memory element” may describe a memory cell or memory element as it is directly after the fabrication process.

The term “condition” may be used herein to include, for example, one or more properties, e.g., of a memory cell. As an example, a memory cell may be in a first condition and may have a first set of properties (e.g., a first value for the low and/or high threshold voltage, a first QV characteristic, and the like) associated therewith, and a memory cell may be in a second condition and may have a second set of properties (e.g., a second value for the low and/or high threshold voltage, a second QV characteristic, and the like) associated therewith. In this case, at least one property of the second set of properties may be different from that property in the first set of properties.

The term “switch” may be used herein to describe a modification of the memory state a memory cell is residing in. For example, in the case that a memory cell is residing in a first memory state (e.g., the LVT state), the memory state the memory cell is residing in may be switched such that, after the switch, the memory cell may reside in a second memory state (e.g., the HVT state), different from the first memory state. The term “switch” may thus be used herein to describe a modification of the memory state a memory cell is residing in, from a first memory state to a second memory state. The term “switch” may also be used herein to describe a modification of a polarization, for example of a spontaneously-polarizable memory element (e.g., of a spontaneously-polarizable layer, such as a remanent-polarizable layer). For example, a polarization of a spontaneously-polarizable memory element may be switched, such that the sign of the polarization varies from positive to negative or from negative to positive, while the absolute value of the polarization may remain in some aspects substantially unaltered. According to various aspects, writing a memory cell may include bringing the memory cell from one of at least two memory states into another one of the at least two memory states of the memory cell (e.g., from the LVT state into the HVT state, or vice versa).

The term “connected” may be used herein with respect to nodes, terminals, integrated circuit elements, and the like, to mean electrically connected, which may include a direct connection or an indirect connection, wherein an indirect connection may only include additional structures in the current path that do not influence the substantial functioning of the described circuit or device. The term “electrically conductively connected” that is used herein to describe an electrical connection between one or more terminals, nodes, regions, contacts, etc., may be understood as an electrically conductive connection with, for example, ohmic behavior, e.g., provided by a metal or degenerate semiconductor in absence of p-n junctions in the current path. The term “electrically conductively connected” may be also referred to as “galvanically connected”.

The term “coupled to” used herein with reference to functional parts of a memory cell (e.g., functional parts of a memory structure) that are coupled to respective nodes (e.g., source-line node, bit-line node, and/or word-line node) of the memory cell may be understood as follows: the respective functional parts are electrically conductively connected to corresponding nodes and/or the respective functional parts itself provide the corresponding nodes. As an example, a source/drain node of a field-effect transistor memory structure may be electrically conductively connected to the source-line node of the memory cell or the source/drain node of the field-effect transistor memory structure may provide the source-line node of the memory cell. As another example, a source/drain node of the field-effect transistor memory structure may be electrically conductively connected to the bit-line node of the memory cell or the source/drain node of the field-effect transistor memory structure may provide the bit-line node of the memory cell.

The term “voltage” may be used herein with respect to “one or more bitline voltages”, “one or more wordline voltages”, “one or more plateline voltages”, “one or more sourceline voltages”, “one or more control line voltages”, “one or more base voltages” and the like. As an example, the term “base voltage” may be used herein to denote a reference voltage and/or a reference potential for the circuit. With respect to an electrical circuit, the base voltage may be also referred to as ground voltage, ground potential, virtual ground voltage, or zero volts (0 V). The base voltage of an electrical circuit may be defined by the power supply used to operate the electronic circuit. As another example, the term “control line voltage” may be used herein to denote a voltage that is provided to a control line, e.g., of a memory cell arrangement (for example a “wordline voltage” may be provided to a “wordline”, a “bitline voltage” may be provided to a bitline, a “sourceline voltage” may be provided to a sourceline, and a “plateline voltage” may be provided to a plateline). The sign of a voltage difference (e.g., a voltage drop) may be defined as a potential inside a memory cell (e.g., at a first electrode portion) minus a potential at a second electrode portion of the memory cell.

Illustratively, a voltage provided to a node or a terminal may assume any suitable value depending on the intended operation of the circuit including the node or terminal. For example, a bitline voltage (referred to as V_{BL} or VBL) may be varied depending on the intended operation of the memory cell arrangement. Analogously, a wordline voltage (referred to as V_{WL} or VWL), a plateline voltage (referred to as V_{PL} or VPL), and/or sourceline voltage (referred to as VSL or VSL) may be varied depending on the intended operation of a memory cell arrangement. A voltage provided to a node or terminal may be defined by the respective potential applied to that node or terminal relative to the base voltage (referred to as V_{B}) of the circuit. Further, a voltage drop associated with two distinct nodes or terminals of a circuit may be defined by the respective voltages/potentials applied at the two nodes or terminals. As an example, a bitline voltage drop associated with a memory cell of a memory cell arrangement (e.g., an electrode of the memory cell) may be defined by the respective voltages/potentials applied at the corresponding memory cell (e.g., the electrode of the memory cell).

In some aspects, two voltages may be compared with one another by relative terms such as “greater”, “higher”, “lower”, “less”, or “equal”, for example. It is understood that, in some aspects, a comparison may include the sign (positive or negative) of the voltage value or, in other aspects, the absolute voltage values (also referred to as the magnitude, or as the amplitude, e.g., of a voltage pulse) are considered for the comparison.

The phrase “a current between” a first terminal or node and a second terminal or node may be used herein to mean a current from the first terminal or node to the second terminal or node as well as a current from the second terminal or node to the first terminal or node.

The phrase “a current through” a terminal, node, or region may be used herein to mean a current from the terminal or node to another terminal, another node, or another region as well as a current to the terminal, node, or region (e.g., from another terminal, another node, or another region).

A current may be detected using a current sense amplifier that outputs a voltage proportional to the current.

The term “region” used with regards to a “source region”, “drain region”, “channel region”, and the like, may be used herein to mean a continuous region of a semiconductor portion (e.g., of a semiconductor wafer or a part of a semiconductor wafer, a semiconductor layer, a fin, a semiconductor nanosheet, a semiconductor nanowire, etc.). In some aspects, the continuous region of a semiconductor portion may be provided by semiconductor material having only one dominant doping type.

According to various aspects, the properties and/or the structure of the memory element, an electrode, an electrically conductive electrode layer, and/or a functional layer as described herein may be evaluated with techniques known in the art. As an example, transmission electron microscopy (TEM) may be used to determine the structure of an electrode, for example the presence of one or more electrode layers and/or the presence of one or more functional layers in the electrode. TEM may be used for identifying a layer, an interface, a crystal structure, a microstructure, and other properties. As another example, X-ray crystallography (X-ray diffraction) may be used to determine various properties of a layer or a material, such as the crystal structure, the lattice properties, the size and shape of a unit cell, the chemical composition, the phase or alteration of the phase, the presence of stress in the crystal structure, the microstructure, and the like. As a further example, energy-dispersive X-ray spectroscopy (EDS) and/or hard x-ray photoelectron spectroscopy (HAXPES) may be used to determine the chemical composition of a layer or a material, e.g. the presence and/or the content of an element in the layer or material. As a further example, Rutherford backscattering spectrometry (RBS) may be used to determine the structure and/or the composition of a material. As a further example, secondary ion mass spectrometry (SIMS) may be used to analyze the molecular composition of the upper monolayers of a solid, e.g. for analyzing the spatial distribution (e.g., the gradient) of an element across the solid.

A composition of a layer, a concentration of one or more materials within the layer, a composition of a layer, and/or a concentration of one or more materials within the spontaneously polarizable memory element, etc. may be determined with techniques known in the art. For example, energy-dispersive X-ray spectroscopy (EDS) (e.g., in combination with scanning electron microcopy (SEM) or transmission electron microscopy (TEM)), Rutherford backscattering spectrometry (RBS), and/or secondary ion mass spectrometry (SIMS) may be used to analyze the composition and/or concentration. However, the composition of the layer, the concentration of the one or more materials within the layer, the composition of the spontaneously polarizable memory element, and/or the concentration of the one or more materials within the spontaneously polarizable memory element may be also apparent from a manufacturing protocol for manufacturing the respective layer. For example, a layer may be manufactured by means of deposition, such as atomic layer deposition (ALD) and the respective composition and/or concentration may be directly apparent from the used deposition protocol (e.g., the used ALD deposition protocol).

The term “thickness” used with regards to a “thickness” of a layer may be used herein to mean the dimension (in other words an extent) of the layer perpendicular to (viz. normal to) the surface of the support (the material or material structure) on which the layer is formed (e.g., deposited or grown). If a surface of the support is parallel to the surface of the carrier (e.g., parallel to the main processing surface) the “thickness” of the layer formed on the surface of the support may be the same as the height of the layer. Hence, a thickness may be measured normal (e.g., perpendicular) to a surface of the below structure (e.g., a three-dimensional, 3D, structure).

The terms “at least one” and “one or more” may be understood to include any integer number greater than or equal to one, i.e. one, two, three, four, [ . . . ], etc. The term “a plurality” or “a multiplicity” may be understood to include any integer number greater than or equal to two, i.e. two, three, four, five, [ . . . ], etc. The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The phrase that an element or a group of elements “includes” another element or another group of elements may be used herein to mean that the other element or other group of elements may be part of the element or the group of elements or that the element or the group of elements may be configured or formed as the other element or the other group of elements (e.g., the element may be the other element).

The phrase “unambiguously assigned” may be used herein to mean a one-to-one-assignment (e.g., allocation, e.g., correspondence) or a bijective assignment. As an example, a first element being unambiguously assigned to a second element may include that the second element is unambiguously assigned to the first element. As another example, a first group of elements being unambiguously assigned to a second group of element may include that each element of the first group of elements is unambiguously assigned to a corresponding element of the second group of elements and that that corresponding element of the second group of elements is unambiguously assigned to the element of the first group of elements.

An “electrically conductive” connection or coupling, as described herein, may include a direct electrical connection or an indirect electrical connection, wherein an indirect connection may include additional structures in the current path that have no influence on the substantial functioning of the described circuit or device.

It is noted that one or more functions described herein with reference to a memory cell, a memory cell arrangement, etc., may be accordingly part of a method, e.g., part of a method for operating a memory cell arrangement. Vice versa, one or more functions described herein with reference to a method, e.g., with reference to a method for operating a memory cell arrangement, may be implemented accordingly in a device or in a part of a device, for example, in a memory cell, a memory cell arrangement, etc.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

1. A method for manufacturing a memory cell arrangement, the method comprising:
forming a plurality of memory cells, wherein each memory cell of the plurality of memory cells comprises a respective spontaneously polarizable memory element in an as-formed condition;
carrying out a preconditioning operation to concurrently bring the respective spontaneously-polarizable memory element of each memory cell of the plurality of memory cells from the as-formed condition into an operable condition to allow for a writing of each of the plurality of memory cells after the preconditioning operation is carried out;
wherein the preconditioning operation comprises providing a periodic precondition signal at each memory cell of the plurality of memory cells, wherein each cycle of the periodic precondition signal comprises a first precondition voltage pulse having a first polarity and a second precondition voltage pulse having a second polarity opposite to the first polarity, and wherein the periodic precondition signal has a frequency equal to or less than 150 Hz.

2. The method according to claim 1,
wherein the precondition signal has a duty cycle greater than or equal to 90%.

3. The method according to claim 1,
wherein an absolute value of a first amplitude of the first precondition voltage pulse is less than or equal to 2.5 V; and
wherein an absolute value of a second amplitude of the second precondition voltage pulse is less than or equal to 2.5 V.

4. The method according to claim 1,
wherein an absolute value of a first amplitude of the first precondition voltage pulse and an absolute value of a second amplitude of the second precondition voltage pulse are less than half of a product of a breakdown field-strength of the respective spontaneously polarizable memory element and a thickness of the respective spontaneously polarizable memory element.

5. The method according to claim 1,
wherein the preconditioning operation further comprises bringing the plurality of memory cells to a preconditioning temperature, the preconditioning temperate being greater than a temperature of the plurality of memory cells during operation.

6. The method according to claim 1,
wherein the frequency, f, of the precondition signal is less than:
$$\frac{{I}_{max} - {I}_{leak} {N}_{cells}}{2 ( ( ‖ + {V}_{A} \vert - \vert - {V}_{A} ‖ ) \frac{{ε}_{SP}}{{t}_{SP}} + 2 {P}_{SW} ) {A}_{cell} {N}_{cells}}$$
wherein the plurality of memory cells comprises a number of N_{cells} memory cells;
wherein each memory cell of the plurality of memory cells comprises a respective spontaneously-polarizable capacitor structure having an area of A_{cell}, the respective spontaneously-polarizable capacitor structure comprising the respective spontaneously-polarizable memory element;
wherein Iₘₐₓ is a maximum power supply current applied to memory cell arrangement during the precondition operation, Iₗₑₐₖ is a leakage current per memory cell of the plurality of memory cells, +V_{A} is a voltage amplitude value of the first precondition voltage pulse, −V_{A} is a voltage amplitude value of the second precondition voltage pulse, ε_{SP} is a permittivity of the respective spontaneously-polarizable memory element, t_{SP} is a thickness of the respective spontaneously-polarizable memory element, and P_{SW} is a maximum switchable polarization of the respective spontaneously-polarizable memory element.

7. The method according to claim 1,
wherein the respective spontaneously polarizable memory element comprises or consists of hafnium oxide, zirconium oxide, or hafnium zirconium oxide.

8. The method according to claim 1,
wherein a difference between an absolute value of a write voltage used for the writing of a respective memory cell of the plurality of memory cells after the preconditioning operation and an absolute value of a first amplitude of the first precondition voltage pulse is less than or equal to 0.5 V, or
wherein a difference between an absolute value of the write voltage used for the writing of the respective memory cell of the plurality of memory cells after the preconditioning operation and an absolute value of a second amplitude of the second precondition voltage pulse is less than or equal to 0.5 V, or
both.

9. The method according to claim 1,
wherein the as-formed condition is a condition of the respective spontaneously-polarizable memory element of a respective memory cell of the plurality of memory cells after forming the spontaneously-polarizable memory element and prior to any cycling operation of the respective memory cell.

10. The method according to claim 1,
wherein the as-formed condition of the respective spontaneously-polarizable memory element is associated with an as-formed magnitude of a remanent polarization of the respective spontaneously-polarizable memory element; and
wherein the operable condition of the respective spontaneously-polarizable memory element is associated with an operable magnitude of the remanent polarization of the respective spontaneously-polarizable memory element, the operable magnitude of the remanent polarization being greater than the as-formed magnitude.

11. The method according to claim 1,
wherein the as-formed condition of the respective spontaneously-polarizable memory element of a respective memory cell of the plurality of memory cells is associated with an as-formed write voltage value for writing the respective memory cell into a memory state of at least two memory states;
wherein the operable condition of the respective spontaneously-polarizable memory element of the respective memory cell is associated with an operable write voltage value for writing the respective memory cell into the memory state, the operable write voltage value being less than the as-formed write voltage value.

12. The method according to claim 1, further comprising:
after carrying out the preconditioning operation, carrying out an endurance test of each memory cell of the plurality of memory cells.

13. The method according to claim 1,
wherein forming the plurality of memory cells comprises forming the plurality of memory cells on a die of a semiconductor substrate; and
wherein the method further comprises packaging the die after the preconditioning operation is carried out.

14. The method according to claim 1, further comprising:
during or prior to carrying out the preconditioning operation, carrying out a sorting of the plurality of memory cells.

15. A method of manufacturing one or more memory devices, the method comprising:
providing a semiconductor substrate that comprises one or more dies, each of the one or more dies comprising a respective plurality of memory cells, each of the respective plurality of memory cells comprising a respective spontaneously polarizable memory element, and
preconditioning the respective plurality of memory cells of each of the one or more dies to bring each memory cell of the respective plurality of memory cells into an operable condition, wherein preconditioning the respective plurality of memory cells of a respective die of the one or more dies comprises concurrently providing a periodic precondition signal at each memory cell of the respective plurality of memory cells, wherein each cycle of the periodic precondition signal comprises a first precondition voltage pulse having a first polarity and a second precondition voltage pulse having a second polarity opposite to the first polarity, and wherein the periodic precondition signal has a frequency equal to or less than 150 Hz; and
packaging the one or more dies to provide one or more memory devices.

16. The method according to claim 15,
wherein the precondition signal has a duty cycle greater than or equal to 90%.

17. The method according to claim 15,
wherein an absolute value of a first amplitude of the first precondition voltage pulse is less than or equal to 2.5 V; and
wherein an absolute value of a second amplitude of the second precondition voltage pulse is less than or equal to 2.5 V.

18. A memory device, comprising:
a plurality of memory cells, wherein each memory cell of the plurality of memory cells comprises a respective spontaneously polarizable memory element;
a control circuit configured to cause a preconditioning operation to concurrently bring the respective spontaneously-polarizable memory element of each memory cell of the plurality of memory cells from an as-formed condition into an operable condition to allow for a writing of each of the plurality of memory cells after the preconditioning is carried out;
wherein the preconditioning operation comprises providing a periodic precondition signal at each memory cell of the plurality of memory cells, wherein each cycle of the periodic precondition signal comprises a first precondition voltage pulse having a first polarity and a second precondition voltage pulse having a second polarity opposite to the first polarity, and wherein the periodic precondition signal has a frequency less than or equal to 150 Hz.

19. The memory device according to claim 18,
wherein the memory device is not packaged.

20. The memory device according to claim 18,
wherein the control circuit is configured to cause the preconditioning operation only once.
